(19) United States
(12) Patent Application Publication
(10) Pub. No.: US 2026/0198118 A1
(43) Pub. Date: Jul. 9, 2026

(54) IMAGE SENSOR WITH ANTIREFLECTIVE LAYER AND METHOD OF MANUFACTURING THE SAME

(71) Applicant: Samsung Electronics Co., Ltd., Suwon-si (KR)

(72) Inventors: Keewon KIM, Suwon-si (KR); Jeongha SHIN, Suwon-si (KR); Jongmin JEON, Suwon-si (KR); Jaesung HUR, Suwon-si (KR)

(21) Appl. No.: 19/440,749

(22) Filed: Jan. 6, 2026

(30) Foreign Application Priority Data
Jan. 8, 2025 (KR) 10-2025-0003004

(51) Int. Cl. H10F 39/00

(52) U.S. Cl. CPC H10F 39/8057; H10F 39/8053

(57) ABSTRACT

An image sensor including a substrate having first and second surfaces, color filters on the second surface of the substrate, and an antireflective layer between the second surface of the substrate and the color filters, wherein a thickness of the antireflective layer between the second surface and a first color filter of the color filters is smaller than a thickness of the antireflective layer between the second surface and a second color filter of the color filters, the antireflective layer between the second surface and the second color filter includes a first sub-antireflective layer and a second sub-antireflective layer that are sequentially stacked, the antireflective layer between the second surface and the first color filter includes the second sub-antireflective layer, the first sub-antireflective layer includes a metal oxide, and the second sub-antireflective layer includes an oxygen element, a metal identical to that of the first sub-antireflective layer, and an impurity.

### CROSS-REFERENCE TO RELATED APPLICATION(S)

This U.S. non-provisional application claims priority under 35 U.S.C. § 119 to Korean Patent Application No. 10-2025-0003004, filed on January 8, 2025, in the Korean Intellectual Property Office, the disclosure of which is herein incorporated by reference in its entirety.

### BACKGROUND

The present disclosure relates to an image sensor.

An image sensor may be a semiconductor device capable of converting optical signals into electrical signals. The image sensor may include a photodiode (PD) as a photodiode. Typically, the photodiode may be formed in a semiconductor substrate and may convert incident light into electrical signals.

Meanwhile, the image sensor may include an antireflective layer on a semiconductor substrate. The antireflective layer may prevent reflection of light so that incident light incident on a light incident surface of the substrate may efficiently reach the photodiode.

### SUMMARY

One object of the present disclosure is directed to providing an image sensor with improved photoelectric conversion efficiency by minimizing light reflection.

Another object of the present disclosure is directed to providing an image sensor with reduced generation of leakage current.

Still another object of the present disclosure is directed to providing an image sensor with improved process efficiency.

An image sensor according to one embodiment of the present disclosure may include a substrate having a first surface and a second surface opposite to the first surface, color filters on the second surface of the substrate, and an antireflective layer between the second surface of the substrate and the color filters, wherein a thickness of the antireflective layer between the second surface and a first color filter of the color filters may be smaller than a thickness of the antireflective layer between the second surface and a second color filter of the color filters, the antireflective layer between the second surface and the second color filter may include a first sub-antireflective layer and a second sub-antireflective layer that are sequentially stacked, the antireflective layer between the second surface and the first color filter may include the second sub-antireflective layer, the first sub-antireflective layer may include a metal oxide, and the second sub-antireflective layer may include an oxygen element, a metal identical to that of the first sub-antireflective layer, and an impurity.

The metal oxide may include titanium oxide (TiOₓ), hafnium oxide (HfOₓ), or tantalum oxide (TaOₓ), the identical metal may be titanium (Ti), hafnium (Hf), or tantalum (Ta), and the impurity is silicon (Si), hafnium (Hf), zirconium (Zr), tantalum (Ta), or aluminum (Al), and includes a material different from the identical metal.

A band gap energy of the second sub-antireflective layer may be greater than a band gap energy of the first sub-antireflective layer.

An optical refractive index of the first sub-antireflective layer may be greater than an optical refractive index of the second sub-antireflective layer.

A thickness of the second sub-antireflective layer may be greater than a thickness of the first sub-antireflective layer.

The image sensor may further include a deep trench isolation pattern provided in the substrate to define pixel regions, wherein the first color filter covers at least one of the pixel regions, the second color filter covers a second one of the pixel regions, and the second color filter is configured to transmit light having a wavelength greater than a wavelength of light transmitted by the first color filter.

The color filters may further include a third color filter covering a third one of the pixel regions, a thickness of the antireflective layer on the third one of the pixel regions is greater than the thickness of the antireflective layer between the first color filter and the second surface, the thickness of the antireflective layer on the third one of the pixel regions is substantially the same as the thickness of the antireflective layer between the second color filter and the second surface, and the antireflective layer on the third one of the pixel regions includes the first sub-antireflective layer and the second sub-antireflective layer that are sequentially stacked.

The third color filter may be configured to transmit light having a wavelength greater than a wavelength of light transmitted by the second color filter.

A third one of the pixel regions is not covered by the color filters, a thickness of the antireflective layer on the third one of the pixel regions is greater than the thickness of the antireflective layer between the first color filter and the second surface, and the antireflective layer on the third one of the pixel regions includes the first sub-antireflective layer and the second sub-antireflective layer that are sequentially stacked.

The image sensor may further include a fixed charge layer between the second surface of the substrate and the antireflective layer, wherein the fixed charge layer includes negative fixed charges.

The image sensor may further include a capping insulating layer provided on an upper surface of the antireflective layer.

The second sub-antireflective layer may be formed by co-deposition or cyclic deposition.

An image sensor according to one embodiment of the present disclosure may include a substrate having a first surface and a second surface opposite to the first surface, a deep trench isolation pattern provided in the substrate to define pixel regions, the pixel regions including a first pixel region, a second pixel region, and a third pixel region, and an antireflective layer provided on the second surface of the substrate to cover the pixel regions and including a first sub-antireflective layer, a second sub-antireflective layer, and a third sub-antireflective layer, a first color filter provided on the antireflective layer and covering the first pixel region, and a second color filter provided on the antireflective layer and covering the second pixel region, wherein a thickness of the antireflective layer on the third pixel region may be greater than a thickness of the antireflective layer on the second pixel region, the thickness of the antireflective layer on the second pixel region may be greater than a thickness of the antireflective layer on the first pixel region, the antireflective layer on the third pixel region may include the first, second, and third sub-antireflective layers that are sequentially stacked, the antireflective layer on the second pixel region may include the second and third sub-antireflective layers that are sequentially stacked, the antireflective layer on the first pixel region may include the third sub-antireflective layer, and an optical refractive index of the first sub-antireflective layer may be greater than an optical refractive index of the second sub-antireflective layer.

The first sub-antireflective layer may include titanium oxide (TiOₓ), hafnium oxide (HfOₓ), or tantalum oxide (TaOₓ), and the second sub-antireflective layer includes at least one of titanium oxide (TiOₓ), hafnium oxide (HfOₓ), or tantalum oxide (TaOₓ), and at least one of silicon (Si), hafnium (Hf), zirconium (Zr), tantalum (Ta), or aluminum (Al).

The third sub-antireflective layer may be formed of a material identical to that of the second sub-antireflective layer.

The image sensor may further include a third color filter provided on the antireflective layer and covering the third pixel region, wherein the first color filter is configured to transmit light having a first wavelength, the second color filter is configured to transmit light having a second wavelength, and the third color filter is configured to transmit light having a third wavelength, and wherein the third wavelength is greater than the second wavelength, and the second wavelength is greater than the first wavelength.

The third pixel region may not be covered by any color filter, and the third pixel region may be configured to detect infrared rays.

An image sensor according to one embodiment of the present disclosure may include a substrate having a first surface and a second surface opposite to the first surface, the substrate including a pixel array region, a pad region provided at one side of the pixel array region, and an optical black region provided between the pixel array region and the pad region, an antireflective layer on the second surface of the substrate, and color filters provided on the antireflective layer and including a first color filter and a second color filter having different colors from each other, wherein the color filters may be provided on the pixel array region, a thickness of the antireflective layer between the second color filter and the second surface may be greater than a thickness of the antireflective layer between the first color filter and the second surface, and greater than a thickness of the antireflective layer on the optical black region and the pad region, the antireflective layer between the second color filter and the second surface may include a first sub-antireflective layer and a second sub-antireflective layer that are sequentially stacked, and the antireflective layer between the first color filter and the second surface may include the second sub-antireflective layer.

The antireflective layer on the optical black region and the pad region may include the second sub-antireflective layer.

The first sub-antireflective layer may include titanium oxide (TiOₓ), hafnium oxide (HfOₓ), or tantalum oxide (TaOₓ), and the second sub-antireflective layer includes at least one of titanium oxide (TiOₓ), hafnium oxide (HfOₓ), or tantalum oxide (TaOₓ), and at least one of silicon (Si), hafnium (Hf), zirconium (Zr), tantalum (Ta), or aluminum (Al).

### BRIEF DESCRIPTION OF DRAWINGS

FIG. 1 is a block diagram of an image sensor according to an example embodiment of the present disclosure.

FIG. 2 is a circuit diagram of pixels included in a pixel array of an image sensor according to an example embodiment of the present disclosure.

FIG. 3A is a cross-sectional view of an image sensor according to an example embodiment of the present disclosure.

FIG. 3B is an enlarged view showing region X of FIG. 3A.

FIG. 4 is a cross-sectional view of an image sensor according to an example embodiment of the present disclosure.

FIG. 5 is a cross-sectional view of an image sensor according to an example embodiment of the present disclosure.

FIG. 6 is a cross-sectional view of an image sensor according to an example embodiment of the present disclosure.

FIG. 7 is a plan view of an image sensor according to an example embodiment of the present disclosure.

FIG. 8 is a cross-sectional view taken along line I-I’ of FIG. 7.

FIG. 9 is a cross-sectional view of an image sensor according to an example embodiment of the present disclosure.

FIG. 10 is a cross-sectional view of an image sensor according to an example embodiment of the present disclosure.

FIGS. 11A to 11D are cross-sectional views illustrating a method for manufacturing an image sensor according to an example embodiment of the present disclosure.

FIGS. 12A to 12D are cross-sectional views illustrating a method for manufacturing an image sensor according to an example embodiment of the present disclosure.

### DETAILED DESCRIPTION

Hereinafter, preferred embodiments of the present disclosure will be described in more detail with reference to the accompanying drawings. Like reference characters refer to like elements throughout the specification and drawings.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes. The term “substantially” may be used herein to emphasize this meaning, unless the context or other statements indicate otherwise.

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

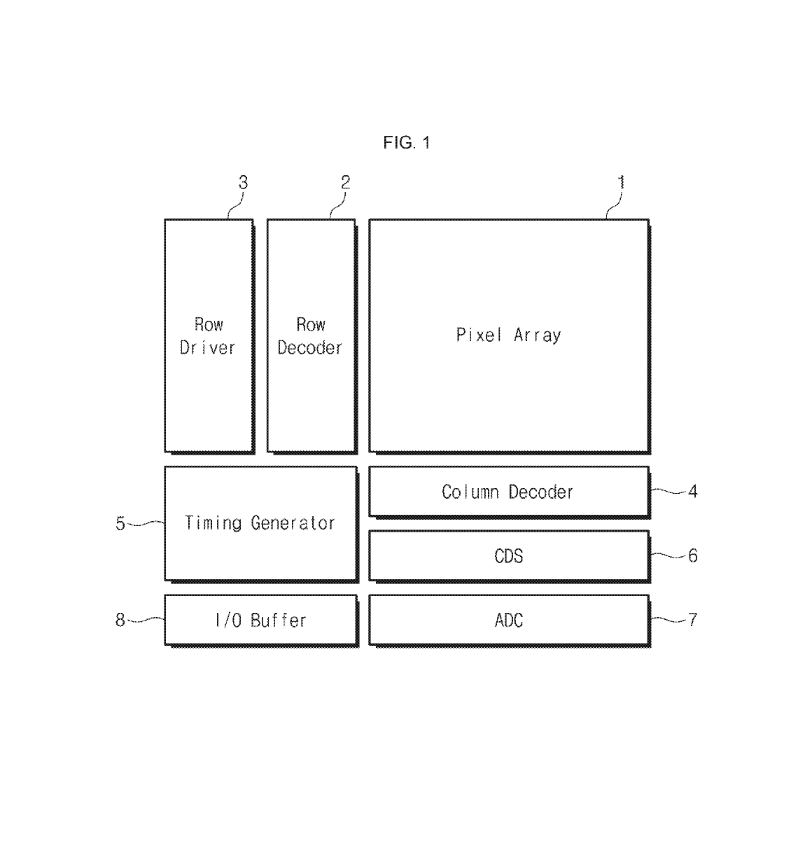

FIG. 1 is a block diagram of an image sensor according to an example embodiment of the present disclosure.

Referring to FIG. 1, an image sensor according to one embodiment of the present disclosure may include a pixel array 1, a row decoder 2, a row driver 3, a column decoder 4, a timing generator 5, a correlated double sampler (CDS) 6, an analog to digital converter (ADC) 7, and an input/output buffer (I/O buffer) 8.

The pixel array 1 may include a plurality of pixels arranged two-dimensionally, and each of the pixels may convert optical signals into electrical signals. The pixel array 1 may be driven by a plurality of driving signals (e.g., a pixel selection signal, a reset signal, and/or a charge transfer signal) transmitted from the row driver 3. The converted electrical signals may be provided to the CDS 6 from the pixels of the pixel array 1.

The row driver 3 may provide the plurality of driving signals for driving the plurality of pixels based on decoded results from the row decoder 2 to the pixel array 1. When the pixels are arranged in a matrix form, the driving signals may be provided in a row unit.

The timing generator 5 may provide a timing signal and a control signal to the row decoder 2 and the column decoder 4.

The CDS 6 may receive the electrical signals generated from the pixel array 1 and may hold and sample the received signals. The CDS 6 may double-sample a specific noise level and a signal level caused by an electrical signal to output a difference level corresponding to the difference between the noise level and the signal level.

The ADC 7 may convert an analog signal corresponding to the difference level output from the CDS 6 into a digital signal and may output the digital signal.

The I/O buffer 8 may latch the digital signals and sequentially output the latched signals to an image signal processor (not shown) based on the decoded results from the column decoder 4.

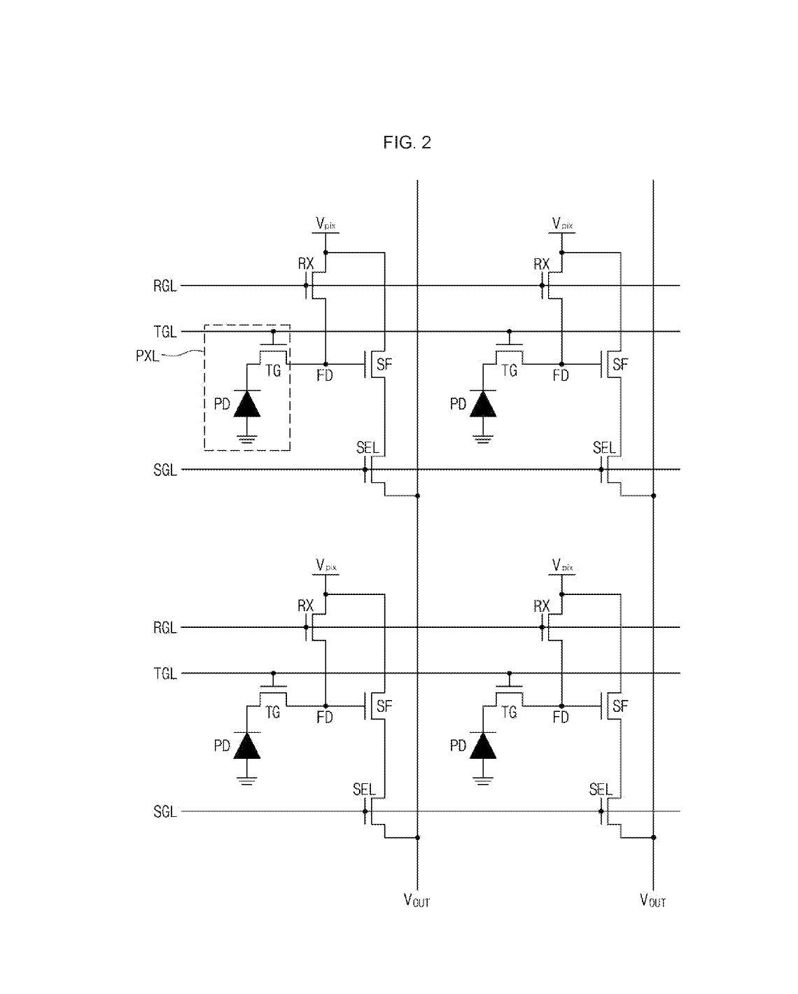

FIG. 2 is a circuit diagram of pixels included in a pixel array of an image sensor according to an example embodiment of the present disclosure.

Referring to FIG. 2, the pixel array may include a plurality of pixels PXL, and the pixels PXL may be arranged in a matrix form. Each of the pixels PXL may include a transfer gate TG of a transistor transistor, the pixel array may include pixel transistors, and the pixel transistors may include the transfer transistor and logic transistors RX, SEL, and SF. The logic transistors RX, SEL, and SF may include a reset transistor RX, a selection transistor SEL, and a source follower transistor SF. In addition, each of the pixels PXL may include a photodiode PD.

The photodiode PD may generate and accumulate photocharges in proportion to an amount of light incident from the outside. The photodiode PD may include a photodiode, a phototransistor, a photogate, a pinned photodiode, or a combination thereof. The transfer transistor may transfer the photocharges generated from the photodiode PD to the floating diffusion region FD. A transfer gate TG of the transfer transistor may be connected to a transfer gate line TGL. The floating diffusion region FD may receive and cumulatively store the photocharges generated from the photodiode PD.

A gate of the source follower transistor SF may be connected to the floating diffusion region FD. A drain terminal of the source follower transistor SF may be connected to a power supply voltage Vₚᵢₓ that may receive a power voltage. The source follower transistor SF may be controlled according to the amount of the photocharges accumulated in the floating diffusion region FD.

The reset transistor RX may periodically reset the charges accumulated in the floating diffusion region FD. A gate of the reset transistor RX may be connected to a reset gate line RGL. A source terminal of the reset transistor RX may be connected to the floating diffusion region FD, and a drain terminal of the reset transistor RX may be connected to the power supply voltage Vₚᵢₓ. When the reset transistor RX is turned on, the power voltage of the power supply voltage Vₚᵢₓ may be applied to the floating diffusion region FD through the reset transistor Rx. In other words, when the reset transistor RX is turned on, the charges accumulated in the floating diffusion region FD may be discharged by the power voltage, thereby resetting the floating diffusion region FD.

The source follower transistor SF may serve as a source follower buffer amplifier. The source follower transistor SF may amplify a potential change in floating diffusion region FD and output the amplified potential change to an output line V_{OUT}.

A gate of the selection transistor SEL may be connected to a selection gate line SGL. A drain terminal of the selection transistor SEL may be connected to a source terminal of the source follower transistor SF, and a source terminal of the selection transistor SEL may be connected to the output line V_{OUT}. The selection transistors SEL to be readout in a row unit may be selected by a selection signal applied through the corresponding selection gate line SGL. When the selection transistor SEL is turned on, the potential change amplified by the source follower transistor SF may be output to the output line V_{OUT} through the selection transistor SEL.

Each of the pixels PXL has a single photodiode PD in FIG. 2, but embodiments of the present disclosure are not limited thereto. In one embodiment, the plurality of pixels PXL may share the floating diffusion region FD and at least one of the logic transistors RX, SEL, and SF. In other words, the plurality of photodiodes PD and the plurality of transfer transistors each corresponding to the plurality of photodiodes PD may share the floating diffusion region FD and at least one of the logic transistors RX, SEL, and SF.

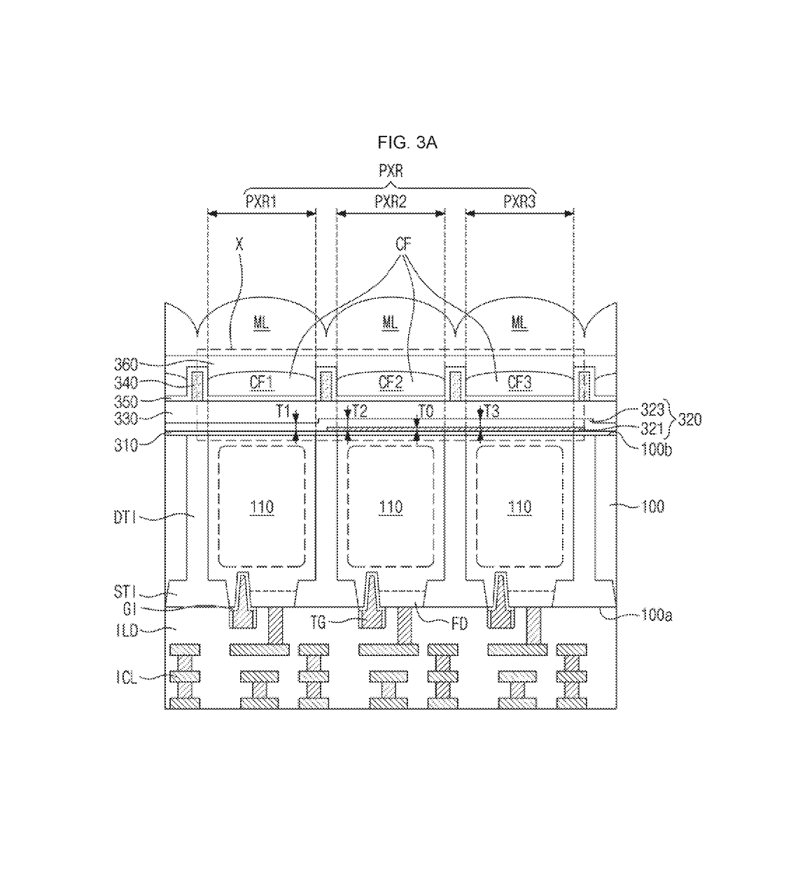

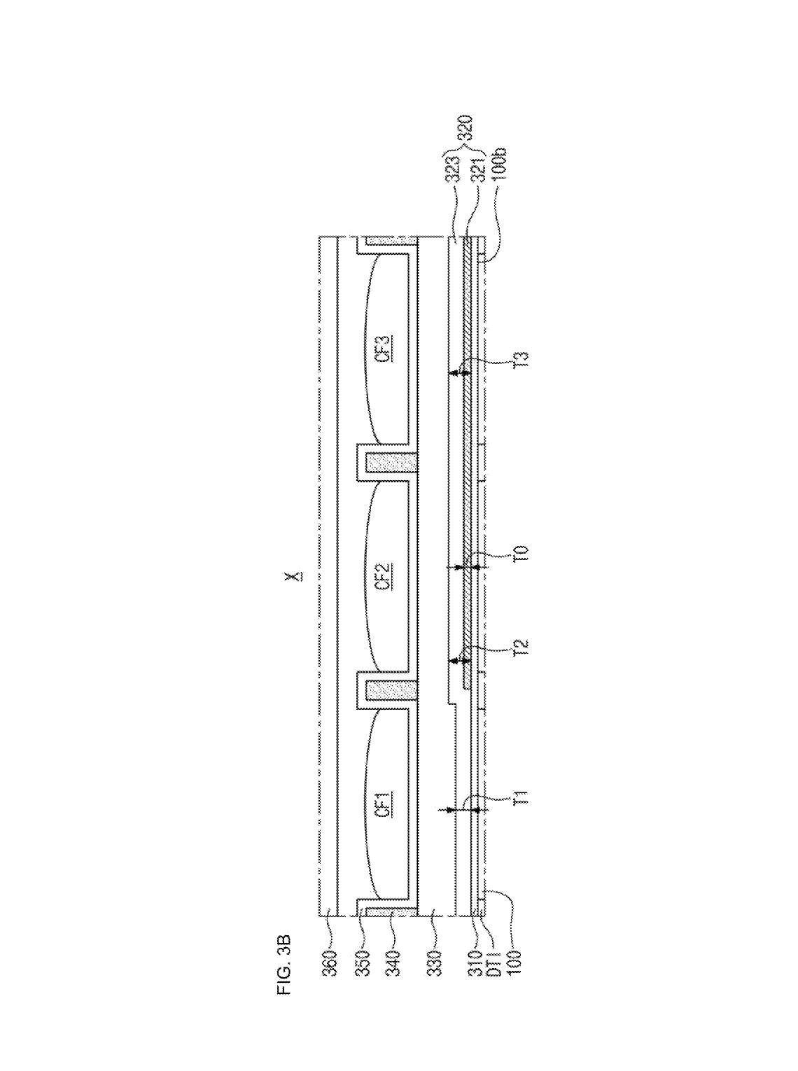

FIG. 3A is a cross-sectional view of an image sensor according to an example embodiment of the present disclosure. FIG. 3B is an enlarged view showing region X of FIG. 3A.

Referring to FIGS. 3A and 3B, an image sensor according to one embodiment of the present disclosure may include a substrate 100, a fixed charge layer 310, an antireflective layer 320, color filters CF, a grid pattern 340, a planarized pattern 360, a deep trench isolation pattern DTI, a shallow trench isolation pattern STI, photodiode regions 110, transfer gates TG, and floating diffusion regions FD.

The substrate 100 may have a first surface 100a and a second surface 100b that are opposite to each other. The first surface 100a of the substrate 100 may be a front surface, and the second surface 100b of the substrate 100 may be a back surface. Light may be incident on the second surface 100b of the substrate 100. For example, the second surface 100b may be a light incident surface.

The substrate 100 may include a semiconductor substrate (e.g., a silicon substrate, a germanium substrate, or a silicon-germanium substrate) or a silicon on insulator (SOI) substrate. The substrate 100 may include impurities of a first conductivity type. Accordingly, the substrate 100 may have the first conductivity type. The impurities of the first conductivity type may be a group III element. For example, the impurities of the first conductivity type may be p-type impurities such as boron (B).

A plurality of pixel regions PXR may be provided in the substrate 100. The pixel regions PXR may be arranged in a matrix form forming rows and columns. For example, as shown in FIG. 3A, the pixel regions PXR may include a first pixel region PXR1, a second pixel region PXR2, and a third pixel region PXR3. The first, second, and third pixel regions PXR1, PXR2, and PXR3 may be configured to detect light of different wavelengths. For example, the first pixel region PXR1 may detect blue light, the second pixel region PXR2 may detect green light, and the third pixel region PXR3 may detect red light. Here, each of the first, second, and third pixel regions PXR1, PXR2, and PXR3 may be a region corresponding to the pixel PXL of FIG. 2.

The fixed charge layer 310 may cover the second surface 100b of the substrate 100. The fixed charge layer 310 may have a single-layered structure or a multi-layered structure. The fixed charge layer 310 may have negative fixed charges. Therefore, holes may accumulate at a location adjacent to the fixed charge layer, for example, at an interface between the fixed charge layer 310 and the substrate 100 and/or at a portion of the substrate 100 adjacent to the second surface 100b. As a result, the fixed charge layer 310 may effectively reduce a dark current and/or a white spot.

In one embodiment, the fixed charge layer 310 may be formed of a metal oxide or a metal fluoride including at least one of hafnium Hf, zirconium Zr, aluminum Al, tantalum Ta, titanium Ti, yttrium Y, or a lanthanoid. For example, the fixed charge layer 310 may be formed of a hafnium oxide or an aluminum oxide.

The color filters CF may be provided on the second surface 100b of the substrate 100. More specifically, the color filters CF may be provided on the antireflective layer 320. The color filters CF may be arranged two-dimensionally on the antireflective layer 320. For example, the color filters CF may be arranged in first and second horizontal directions that are parallel to an upper surface of the substrate 100 and perpendicular to each other. A plurality of color filters CF arranged two-dimensionally may form a color filter array.

According to some embodiments, four pixels PXL (see FIG. 2) arranged in a 2x2 matrix form may implement the same color. Alternatively, each of four pixels PXL (see FIG. 2) arranged in a 2x2 matrix form may implement one of red, green, and blue colors. For example, the four pixels PXL (see FIG. 2) may implement colors of red, green, green, and blue in order.

The color filters CF may be disposed for each of the pixel regions PXR on the second surface 100b of the substrate 100. For example, each of the color filters CF may be provided at a position corresponding to one of the photodiode regions 110. Specifically, the color filters CF may cover the pixel regions PXR.

Each of the color filters CF may be selected from one of a plurality of reference colors. Examples of the plurality of reference colors may include, RGB (red, green, blue), RGBW (red, green, blue, white), CMY (cyan, magenta, yellow), CMYK (cyan, magenta, yellow, black), RYB (red, yellow, blue), and RGBIR (red, green, blue, and infrared rays). Therefore, the color filters CF may transmit visible light of various colors. However, the colors of the color filters CF are not limited thereto, and filters of other colors may also be provided.

In one embodiment, the color filters CF may include a first color filter CF1 and a second color filter CF2 that have different colors. For example, the first color filter CF1 may be blue, and the second color filter CF2 may be green. The first and second color filters CF1 and CF2 may be configured to transmit light of different wavelengths by having different colors. For example, the second color filter CF2 may transmit light having a wavelength greater than that of the first color filter CF1.

In one embodiment, the first color filter CF1 may cover at least one of the pixel regions PXR. For example, the first color filter CF1 may cover the first pixel region PXR1. In addition, the second color filter CF2 may cover at least another one of the pixel regions PXR. For example, the second color filter CF2 may cover the second pixel region PXR2.

In one embodiment, the color filters CF may further include a third color filter CF3. The third color filter CF3 may have a color different from those of the first and second color filters CF1 and CF2. For example, the third color filter CF3 may be red. The third color filter CF3 may be configured to transmit light of a wavelength different from those of the first and second color filters CF1 and CF2. For example, the third color filter CF3 may transmit light having a wavelength greater than that of the second color filter CF2. In addition, the third color filter CF3 may transmit light having a wavelength greater than that of the first color filter CF1. For example, the third color filter CF3 may transmit red light, the second color filter CF2 may transmit green light, and the first color filter CF1 may transmit blue light.

In one embodiment, the third color filter CF3 may cover still another one of the pixel regions PXR. For example, the third color filter CF3 may cover the third pixel region PXR3.

The antireflective layer 320 may be provided between the second surface 100b of the substrate 100 and the color filters CF. For example, the antireflective layer 320 may be provided on an upper surface of the fixed charge layer 310. In example embodiments, the antireflective layer 320 may contact the upper surface of the fixed charge layer 310. The antireflective layer 320 may reduce or minimize reflection of light incident on the second surface 100b. The antireflective layer 320 may have a multi-layered structure.

In one embodiment, the antireflective layer 320 may include a first sub-antireflective layer 321 and a second sub-antireflective layer 323. The first sub-antireflective layer 321 may be provided on the upper surface of the fixed charge layer 310. In example embodiments, the first sub-antireflective layer 321 may contact the upper surface of the fixed charge layer 310. For example, the first sub-antireflective layer 321 may be provided over the second pixel region PXR2. For example, the first sub-antireflective layer 321 may be provided over the third pixel region PXR3. For example, the first sub-antireflective layer 321 may cover the second and third pixel regions PXR2 and PXR3. In example embodiments, the first sub-antireflective layer 321 may extend between the second color filter CF2 and the second pixel region PXR2, and between the third color filter CF3 and the third pixel region PXR3. For example, the first sub-antireflective layer 321 may vertically overlap the second and third color filters CF2 and CF3 and the second and third pixel regions PXR2 and PXR3.

The first sub-antireflective layer 321 may be formed of or include a metal oxide. For example, the first sub-antireflective layer 321 may be formed of or include titanium oxide TiOₓ, hafnium oxide HfOₓ, or tantalum oxide TaOₓ. For example, the first sub-antireflective layer 321 may consist of TiO₂.

The second sub-antireflective layer 323 may be provided on the first sub-antireflective layer 321 and the fixed charge layer 310. The second sub-antireflective layer 323 may cover the first sub-antireflective layer 321. The second sub-antireflective layer 323 may contact upper and side surfaces of the first sub-antireflective layer 321. For example, the second sub-antireflective layer 323 may be spaced apart from the fixed charge layer 310 by the first sub-antireflective layer 321. The second sub-antireflective layer 323 may cover the pixel regions PXR. For example, the second sub-antireflective layer 323 may be provided over the first, second, and third pixel regions PXR1, PXR2, and PXR3.

The second sub-antireflective layer 323 may include an oxygen element, a metal identical to that of the first sub-antireflective layer 321, and an impurity. For example, the identical metal may be titanium Ti, hafnium Hf, or tantalum Ta, and the impurity may be silicon Si, hafnium Hf, zirconium Zr, tantalum Ta, or aluminum Al. Here, the impurity may be a material different from the identical metal.

More specifically, the second sub-antireflective layer 323 may include a material in which a metal oxide is doped with an impurity. For example, the second sub-antireflective layer 323 may include a material in which titanium oxide TiOₓ is doped with hafnium, zirconium, tantalum, or aluminum, a material in which hafnium oxide HfOₓ is doped with zirconium, tantalum, or aluminum, or a material in which tantalum oxide TaOₓ is doped with hafnium, zirconium, or aluminum. For example, the second sub-antireflective layer 323 may be formed of a material in which TiO_{₂} is doped with silicon.

In one embodiment, a band gap energy of the second sub-antireflective layer 323 may be greater than a band gap energy of the first sub-antireflective layer 321. For example, the band gap energy of the second sub-antireflective layer 323 may be about 9 eV. For example, the band gap energy of the first sub-antireflective layer 321 may be about 3.3 eV. For example, the band gap energy of the second sub-antireflective layer 323 may be two to three times greater than the band gap energy of the first sub-antireflective layer 321.

In one embodiment, an optical refractive index of the first sub-antireflective layer 321 may be greater than an optical refractive index of the second sub-antireflective layer 323. For example, the optical refractive index of the first sub-antireflective layer 321 may be about 2.3 to about 2.4. For example, the optical refractive index of the second sub-antireflective layer 323 may be about 2.3 to about 2.0.

In one embodiment, a thickness T1 of the second sub-antireflective layer 323 may be greater than a thickness T0 of the first sub-antireflective layer 321. For example, the thickness of the second sub-antireflective layer 323 may be about 26 nm. For example, the thickness of the first sub-antireflective layer 321 may be about 13 nm. However, the thicknesses of the first and second sub-antireflective layers 321 and 323 are not limited thereto and the first and second sub-antireflective layers 321 and 323 may have various thicknesses. As used herein, the term “thickness” may refer to the thickness or height measured in a direction perpendicular to a top surface of the substrate 100.

In one embodiment, the thickness T1 of the antireflective layer 320 between the second surface 100b of the substrate 100 and the first color filter CF1 may be smaller than a thickness T2 of the antireflective layer 320 between the second surface 100b and the second color filter CF2. In addition, the thickness T2 of the antireflective layer 320 between the second surface 100b of the substrate 100 and the second color filter CF2 may be substantially the same as a thickness T3 of the antireflective layer 320 between the second surface 100b of the substrate 100 and the third color filter CF3.

More specifically, the thickness T3 of the antireflective layer 320 on the third pixel region PXR3 may be greater than the thickness T1 of the antireflective layer 320 on the first pixel region PXR1. In addition, the thickness T3 of the antireflective layer 320 on the third pixel region PXR3 may be substantially the same as the thickness T2 of the antireflective layer 320 on the second pixel region PXR2.

The image sensor according to one embodiment of the present disclosure may minimize light reflectance by providing the first and second sub-antireflective layers 321 and 323 with the above-described material compositions, thicknesses, optical refractive indices, and/or band gap energies. As a result, the photoelectric conversion efficiency of the image sensor may be improved.

In one embodiment, the image sensor may further include a capping insulating layer 330. The capping insulating layer 330 may be provided on an upper surface of the antireflective layer 320. The capping insulating layer 330 may contact the upper surface of the antireflective layer 320. The capping insulating layer 330 may have an upper surface that extends continuously at the same vertical level, and a lower surface that is provided at different vertical levels. For example, the lower surface of the capping insulating layer 330 on the first pixel region PXR1 may be at a vertical level that is lower than a vertical level of the lower surface of the capping insulating layer 330 on the second and third pixel regions PXR2 and PXR3. A thickness of the capping insulating layer 330 may be the same over each of the first, second, and third pixel regions PXR1, PXR2, and PXR3. The capping insulating layer 330 may be provided over the fixed charge layer 310 with the antireflective layer 320 interposed therebetween. In one embodiment, the capping insulating layer 330 may have a multi-layered structure. For example, the capping insulating layer 330 may have a two-layer structure including a silicon oxide layer and a hafnium oxide layer. The capping insulating layer 330 may include at least one of a titanium oxide, a silicon nitride, a silicon oxide, or a hafnium oxide. The capping insulating layer 330 may include, for example, SiO₂, HfO₂, or Al₂O₃.

The grid pattern 340 may be provided between the color filters CF. The grid pattern 340 may have a grid shape having openings in a plan view. In some embodiments, each of the openings of the grid pattern 340 may vertically overlap one of the pixel regions PXR. The grid pattern 340 may guide incident light so that the incident light is incident on the photodiode regions 110. In some embodiments, the grid pattern 340 may include a light-shielding pattern and/or a low refractive pattern. For example, the light-shielding pattern may be formed of or include at least one of titanium, titanium nitride, tantalum, tantalum nitride, or tungsten. The low refractive pattern may have a refractive index lower than refractive indices of the color filters CF. For example, the low refractive pattern may have a refractive index of about 1.1 to about 1.3. For example, the low refractive pattern may include an organic material.

In one embodiment, the grid pattern 340 may vertically overlap the deep trench isolation pattern DTI. However, the embodiments of the present disclosure are not limited thereto. In one embodiment, the grid pattern 340 may have a structure offset laterally from the deep trench isolation pattern DTI. The offset structure may be intentionally selected to optimize an optical path considering a margin in a manufacturing process and/or a traveling angle of incident light, etc.

In one embodiment, the image sensor may further include a protective layer 350. The protective layer 350 may conformally cover a surface (e.g., an upper and side surfaces) of the grid pattern 340 and the capping insulating layer 330 exposed by openings of the grid pattern 340. For example, the protective layer 350 may contact the upper and side surfaces of the grid pattern 340 and portions of the upper surface of the capping insulating layer 330 that are exposed by openings of the grid pattern 340. In some embodiments, the protective layer 350 may be formed of an insulating material having a high dielectric constant. For example, the protective layer 350 may include an aluminum oxide or a hafnium oxide.

The planarized pattern 360 may be provided on the color filters CF. For example, the planarized pattern 360 may cover upper surfaces of the color filters CF. In example embodiments, the planarized pattern 360 may contact upper surfaces of the color filers CF and upper and side surfaces of the protective layer 350 between adjacent ones of the color filters CF. The planarized pattern 360 may have a flat upper surface. The planarized pattern 360 may be provided on the color filters CF and may perform a function of planarizing upper portions of the color filters CF to facilitate subsequent processes.

In one embodiment, the planarized pattern 360 may include silicon oxide SiO₂, titanium oxide TiO₂, aluminum oxide Al₂O₃, tantalum oxide Ta₂O₅, hafnium oxide HfO₂, or a combination thereof. In addition, the planarized pattern 360 may include at least one of organic materials, for example, an organic polymer. The organic polymer may include, for example, an epoxy resin, polyimide, polycarbonate, polyacryl, polymethyl methacrylate (PMMA), or a combination thereof, but is not limited thereto.

The deep trench isolation pattern DTI may be formed in the substrate 100. The deep trench isolation pattern DTI may isolate and partition the pixel regions PXR. For example, the deep trench isolation pattern DTI may be provided between the pixel regions PXR of the substrate 100. For example, the deep trench isolation pattern DTI may define the pixel regions PXR. An upper surface of the deep trench isolation pattern DTI may be coplanar with the second surface 100b of the substrate 100. For example, the deep trench isolation pattern DTI may include at least one of a silicon oxide layer, a silicon nitride layer, and a silicon oxynitride layer.

The shallow trench isolation pattern STI may be provided in the substrate 100 to define active regions. Each of the active regions may be defined in each of the pixel regions PXR. The active region may be a portion of the substrate 100 surrounded by the shallow trench isolation pattern STI in a plan view. The shallow trench isolation pattern STI may be buried into the inside of the substrate 100 from the first surface 100a of the substrate 100. In addition, a lower surface of the shallow trench isolation pattern STI may be exposed by the first surface 100a. For example, the shallow trench isolation pattern STI may be adjacent to the first surface 100a of the substrate 100. For example, the shallow trench isolation pattern STI may include at least one of a silicon oxide layer, a silicon nitride layer, and a silicon oxynitride layer.

In one embodiment, the deep trench isolation pattern DTI and the shallow trench isolation pattern STI may be connected to each other. For example, the deep trench isolation pattern DTI and the shallow trench isolation pattern STI may be formed of the same material.

The photodiode region 110 may be provided in the substrate 100. Each of the photodiode regions 110 may correspond to one of the pixel regions PXR of the substrate 100. The photodiode region 110 may be a region corresponding to the photodiode PD described in FIG. 2. The photodiode region 110 may be interposed between the first surface 100a and the second surface 100b of the substrate 100. The photodiode region 110 may be disposed at a position spaced apart from the second surface 100b of the substrate 100.

The photodiode region 110 may be a doped region including impurities of a second conductivity type. The impurities of the second conductivity type may have a conductivity type opposite to that of the impurities of the first conductivity type. In one embodiment, the photodiode regions 110 may include a group V element, and the group V element may be the impurities of the second conductivity type. The impurities of the second conductivity type may include n-type impurities such as phosphorus, arsenic, bismuth, and/or antimony.

The transfer gate TG may be disposed on the first surface 100a of the substrate 100 and may be disposed on a corresponding active region of each of the pixel regions PXR. A gate insulating layer GI may be disposed between the transfer gate TG and the corresponding active region. In one embodiment, the transfer gate TG may fill a gate trench recessed into the corresponding active region from the first surface 100a. In this case, the gate insulating layer GI may extend and also be disposed between the transfer gate TG and an inner surface of the gate trench. When the transfer gate TG fills the gate trench, the transfer transistor including the transfer gate TG may be a vertical channel type transistor.

The floating diffusion region FD may be provided in the corresponding active region on one side of the transfer gate TG. The floating diffusion region FD may be provided between the transfer gate TG and the shallow trench isolation STI. The floating diffusion region FD may be a region doped with impurities. The floating diffusion region FD may include impurities of the second conductivity type. When light is incident into the photodiode region 110, photocharges may be generated and accumulated in the photodiode region 110. When the transfer transistor is turned on, the accumulated photocharges may be transferred to the floating diffusion region FD through the transfer transistor.

Interlayer insulating layers ILD may be formed on the first surface 100a of the substrate 100. Wiring lines ICL may be formed on the first surface 100a of the substrate 100. The wiring lines ICL may be formed between the interlayer insulating layers ILD. The wiring lines ICL may include wirings and contact plugs. The wiring lines ICL may pass through the interlayer insulating layers ILD and may be connected to the floating diffusion regions FD of the first, second, and third pixel regions PXR1, PXR2, and PXR3.

Microlenses ML may be provided on the planarized pattern 360. Each of the microlenses ML may be provided on the corresponding color filter CF. The microlenses ML may condense the incident light. As shown in FIG. 3A, each of the microlenses ML may vertically overlap one of the photodiode regions 110. Alternatively, each of the microlenses ML may vertically overlap a plurality of photodiode regions 110 that are adjacent to each other. For example, each of the microlenses ML may vertically overlap the photodiode regions 110 arranged in a 2×2 matrix form, a 3×3 matrix form, or a 4×4 matrix form. In some embodiments, the number of photodiode regions 110 overlapping at least one of the microlenses ML may differ from the number of photodiode regions 110 overlapping at least another one of the microlenses ML. For example, the at least one of the microlens ML may vertically overlap a pair of photodiode regions 110 that are adjacent to each other, and the at least another one of the microlens ML may vertically overlap a single photodiode region 110 or the photodiode regions 110 that are adjacent to each other.

Each of the microlenses ML may have a convex shape facing upward in a cross-sectional view. In some embodiments, each of the microlenses ML may have a circular shape or an elliptical shape in a plan view. The microlenses ML may be formed of a light-transmissive resin.

Although not shown, an additional protective layer may be provided on surfaces of the microlenses ML. The additional protective layer may protect the microlenses ML and transmit light. The additional protective layer may be formed of an organic material and/or an inorganic material. For example, the additional protective layer may include at least one of a silicon oxide, a silicon nitride, a silicon oxynitride, a silicon carbide, a silicon carbo-oxide, a silicon carbo-nitride, a silicon carbo-oxynitride, an aluminum oxide, a zinc oxide, or a hafnium oxide.

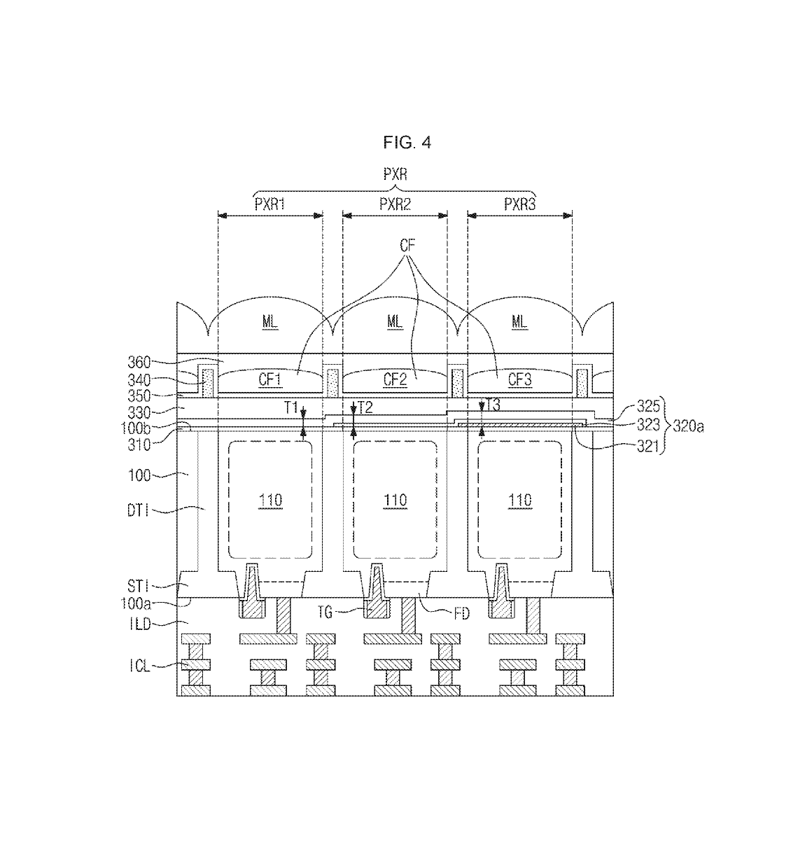

FIG. 4 is a cross-sectional view of an image sensor according to an example embodiment of the present disclosure. For convenience of explanation, the following description will focus on the differences from the above-described embodiment, and duplicative descriptions may not be repeated.

Referring to FIG. 4, an antireflective layer 320a may include a first sub-antireflective layer 321, a second sub-antireflective layer 323, and a third sub-antireflective layer 325. The first sub-antireflective layer 321 may be provided on the fixed charge layer 310. The first sub-antireflective layer 321 may cover, for example, the third pixel region PXR3.

The second sub-antireflective layer 323 may be provided on the fixed charge layer 310 with the first sub-antireflective layer 321 interposed therebetween. The second sub-antireflective layer 323 may cover the first sub-antireflective layer 321. The second sub-antireflective layer 323 may contact upper and side surfaces of the first sub-antireflective layer 321 and an upper surface of the fixed charge layer 310. The second sub-antireflective layer 323 may cover, for example, the second and third pixel regions PXR2 and PXR3. The second sub-antireflective layer 323 may not extend to cover, for example, the first pixel region PXR1.

The third sub-antireflective layer 325 may be provided on the fixed charge layer 310 with the first and second sub-antireflective layers 321 and 323 that are interposed therebetween. The third sub-antireflective layer 325 may conformally cover the fixed charge layer 310 and the first and second sub-antireflective layers 321 and 323. The third sub-antireflective layer 325 may contact upper surfaces of the fixed charge layer 310 and the second sub-antireflective layer 323.

The third sub-antireflective layer 325 may be formed of a material identical to that of the second sub-antireflective layer. For example, the third sub-antireflective layer 325 may include a material in which a metal oxide is doped with an impurity. For example, the second sub-antireflective layer 323 may include a material in which titanium oxide TiOₓ is doped with hafnium, zirconium, tantalum, or aluminum, a material in which hafnium oxide HfOₓ is doped with zirconium, tantalum, or aluminum, or a material in which tantalum oxide TaOₓ is doped with hafnium, zirconium, or aluminum. For example, the second sub-antireflective layer 323 may be formed of a material in which TiO₂ is doped with silicon.

In one embodiment, a thickness T3 of the antireflective layer 320a on the third pixel region PXR3 may be greater than a thickness T2 of the antireflective layer 320a on the second pixel region PXR2. In addition, the thickness T2 of the antireflective layer 320a on the second pixel region PXR2 may be greater than a thickness T1 of the antireflective layer 320a on the first pixel region PXR1. For example, the thickness T3 of the antireflective layer 320a on the third pixel region PXR3 may be the greatest, and the thickness T1 of the antireflective layer 320a on the first pixel region PXR1 may be the smallest.

The image sensor according to one embodiment of the present disclosure may minimize light reflectance by having the first, second, and third sub-antireflective layers 321, 323, and 325 with the above-described thicknesses. As a result, the photoelectric conversion efficiency of the image sensor may be improved.

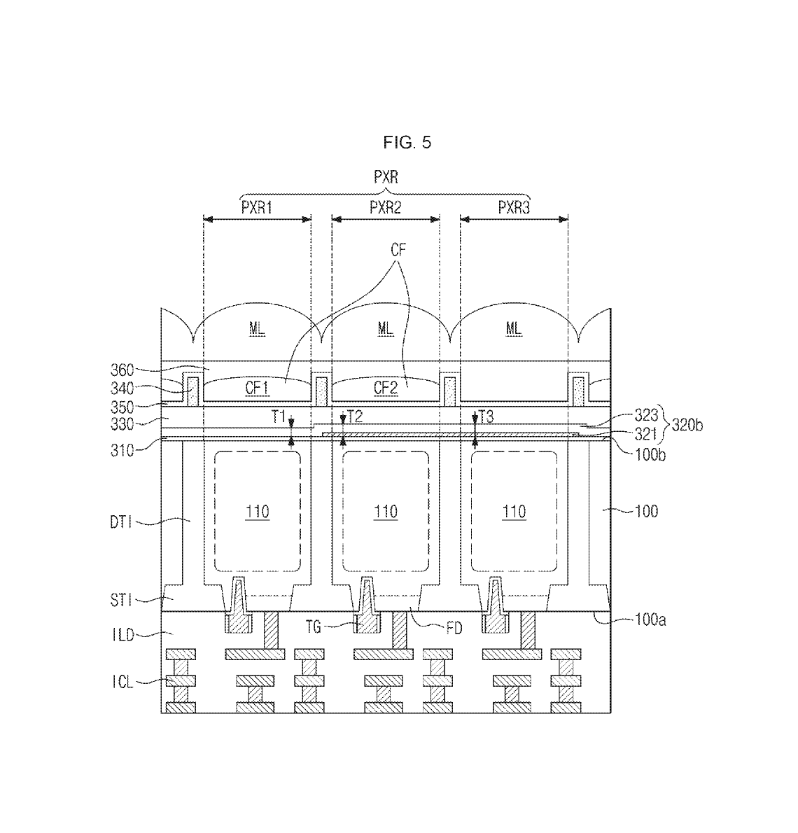

FIG. 5 is a cross-sectional view of an image sensor according to an example embodiment of the present disclosure. For convenience of explanation, the following description will focus on the differences from the above-described embodiment, and duplicative descriptions may not be repeated.

Referring to FIG. 5, an image sensor according to one embodiment of the present disclosure may detect both visible light and infrared rays. For example, some portions of the pixel regions PXR may be configured to detect visible light, and other portions of the pixel regions PXR, excluding the above some portions, may be configured to detect infrared rays. For example, each of the first pixel region PXR1 and the second pixel region PXR2 may detect blue, green, or red light. For example, the third pixel region PXR3 may detect infrared rays.

In one embodiment, the first color filter CF1 may cover at least one of the pixel regions PXR, and the second color filter CF2 may cover at least another one of the pixel regions PXR. In addition, still another one of the pixel regions PXR may not be covered by the color filters CF.

For example, the first color filter CF1 may cover the first pixel region PXR1, and the second color filter CF2 may cover the second pixel region PXR2. In addition, the third pixel region PXR3 may not be covered by the color filter CF. In this case, a space not covered by the color filter CF may be filled with the planarized pattern 360. Therefore, the third pixel region PXR3 may detect infrared rays.

In one embodiment, an antireflective layer 320b on the third pixel region PXR3 may include a first sub-antireflective layer 321 and a second sub-antireflective layer 323 that are sequentially stacked. And, the antireflective layer 320b on the second pixel region PXR2 may also include the first sub-antireflective layer 321 and the second sub-antireflective layer 323 that are sequentially stacked. For example, the first sub-antireflective layer 321 may cover the second and third pixel regions PXR2 and PXR3. In addition, the antireflective layer 320b on the first pixel region PXR1 may include only the second sub-antireflective layer 323. In this case, the second color filter CF2 may transmit light having a wavelength greater than that of the first color filter CF1.

In one embodiment, a thickness T3 of the antireflective layer 320b on the third pixel region PXR3 may be greater than a thickness T1 of the antireflective layer 320b on the first pixel region PXR1. In addition, the thickness T3 of the antireflective layer 320b on the third pixel region PXR3 may be substantially the same as a thickness T2 of the antireflective layer 320b on the second pixel region PXR2.

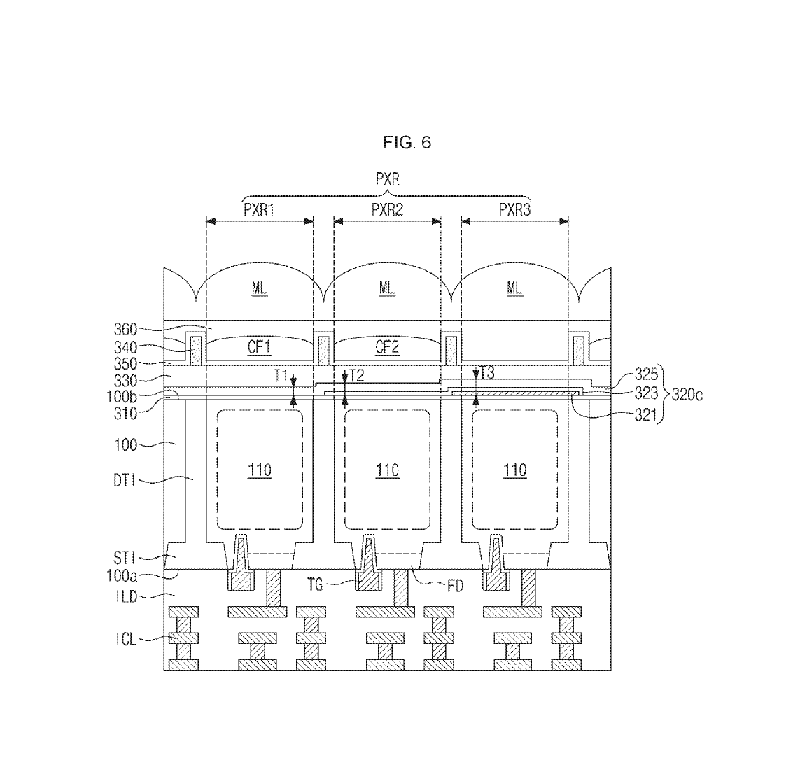

FIG. 6 is a cross-sectional view of an image sensor according to an example embodiment of the present disclosure. For convenience of explanation, the following description will focus on the differences from the above-described embodiments, and duplicative descriptions may not be repeated.

Referring to FIG. 6, even in the case of an image sensor capable of detecting both visible light and infrared rays, an antireflective layer 320c may be formed in a three-layer structure. For example, the antireflective layer 320c may include first, second, and third sub-antireflective layers 321, 323, and 325.

More specifically, the first sub-antireflective layer 321 may be formed on the third pixel region PXR3, the second sub-antireflective layer 323 may be formed on the second and third pixel regions PXR2 and PXR3, and the third sub-antireflective layer 325 may be formed on all of the pixel regions PXR. In other words, the antireflective layer 320c on the third pixel region PXR3 may include the first, second, and third sub-antireflective layers 321, 323, and 325 that are sequentially stacked, the antireflective layer 320c on the second pixel region PXR2 may include the second and third sub-antireflective layers 323 and 325 that are sequentially stacked, and the antireflective layer 320c on the first pixel region PXR1 may include only the third sub-antireflective layer 325.

In addition, the first color filter CF1 may be formed on the first pixel region PXR1, and the second color filter CF2 may be formed on the second pixel region PXR2. Here, the third pixel region PXR3 may not be covered by a color filter CF. In this case, a space not covered by the color filter CF may be filled with the planarized pattern 360. Therefore, the third pixel region PXR3 may detect infrared rays.

In one embodiment, the third sub-antireflective layer 325 may be formed of a material identical to that of the second sub-antireflective layer 323. In addition, the second color filter CF2 may transmit light having a wavelength greater than that of the first color filter CF1. In addition, the third pixel region PXR3 may detect light having a wavelength greater than that of light detected by the first and second pixel regions PXR1 and PXR2. For example, the third pixel region PXR3 may detect infrared rays, and the first and second pixel regions PXR1 and PXR2 may detect visible light.

The image sensor according to one embodiment of the present disclosure may minimize light reflectance by varying the thickness of the antireflective layer 320 according to the wavelength of the transmitted light. As a result, the photoelectric conversion efficiency of the image sensor may be improved.

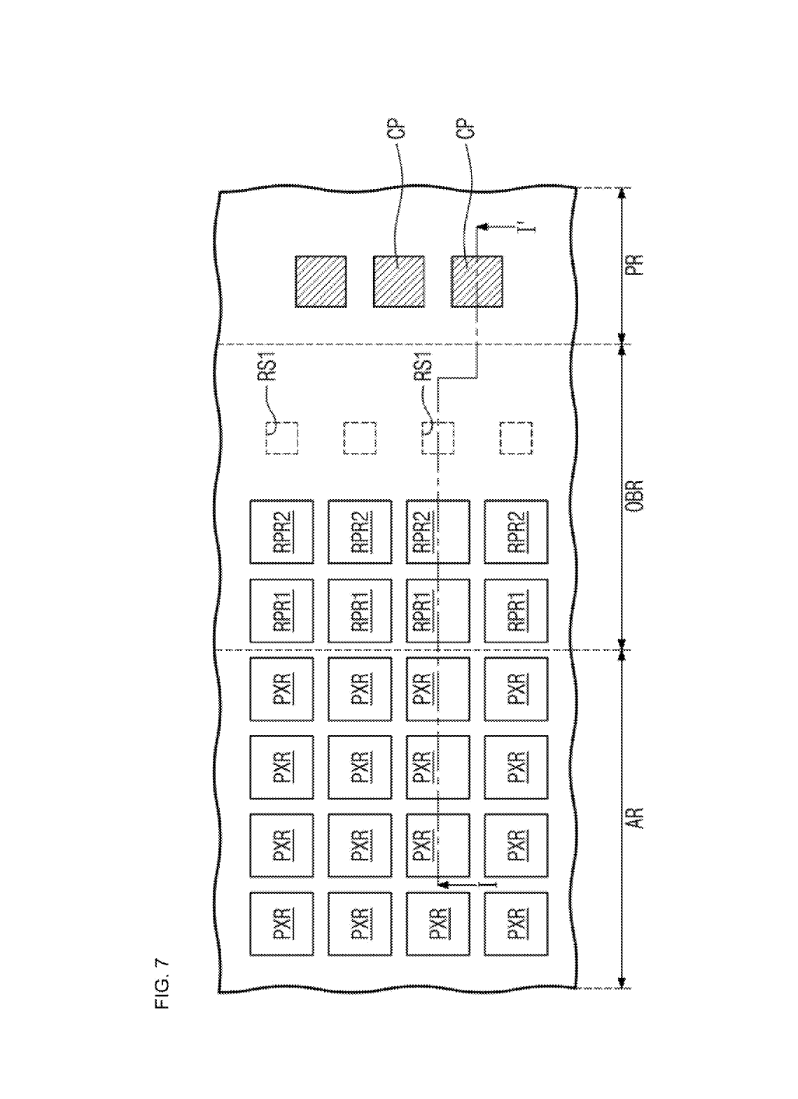

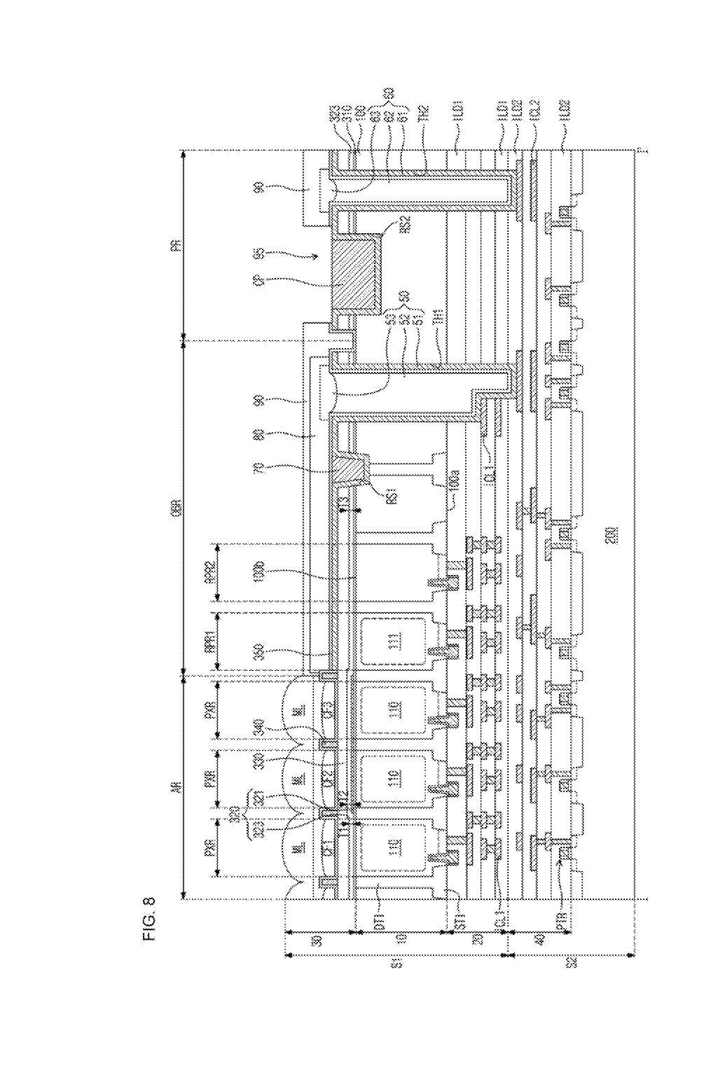

FIG. 7 is a plan view of an image sensor according to an example embodiment of the present disclosure. FIG. 8 is a cross-sectional view taken along line I-I’ of FIG. 7. For convenience of explanation, the following description will focus on the differences from the above-described embodiment, and duplicative descriptions may not be repeated.

Referring to FIGS. 7 and 8, the image sensor according to one embodiment of the present disclosure may include a first structure S1 and a second structure S2. The first structure S1 may be stacked on the second structure S2. That is, the image sensor may have a stacked structure. The first structure S1 may be referred to as a sensor chip or a first chip. The second structure S2 may be referred to as a logic chip or a second chip. The first structure S1 and the second structure S2 may be bonded to each other by at least one of various bonding methods, and may be electrically connected to each other by at least one of various connection methods.

The first structure S1 may include a photoelectric conversion layer 10, a light transmission layer 30, and a first wiring layer 20. The photoelectric conversion layer 10 may be disposed between the light transmission layer 30 and the first wiring layer 20. The photoelectric conversion layer 10 may include a first substrate 100, and the first substrate 100 may include a pixel array region AR, an optical black region OBR, and a pad region PR.

The optical black region OBR may be disposed between the pixel array region AR and the pad region PR in a plan view. In some embodiments, the optical black region OBR may surround the pixel array region AR in a plan view, and the pad region PR may surround the pixel array region AR and the optical black region OBR in a plan view. For example, in a plan view, the pixel array region AR may correspond to a central portion of the first substrate 100, and the optical black region OBR and the pad region PR may correspond to edge portions of the first substrate 100. However, the embodiments of the present application are not limited thereto. In some embodiments, the optical black region OBR and the pad region PR may be provided at one or some of the four sides of the pixel array region AR in a plan view.

A deep trench isolation pattern DTI may be provided in the first substrate 100 to define a plurality of pixel regions PXR. The pixel regions PXR may be defined in the pixel array region AR. The deep trench isolation pattern DTI may also be provided in the optical black region OBR to define one or more reference pixel regions RPR1 and RPR2 in the optical black region OBR. In some embodiments, the reference pixel regions RPR may include a first reference pixel region RPR1 and a second reference pixel region RPR2.

A shallow trench isolation pattern STI may be provided in the first substrate 100 to define at least one active region in each of the pixel regions PXR. In addition, the shallow trench isolation pattern STI may define at least one active region in each of the first and second reference pixel regions RPR1, RPR2.

Each of photodiode regions 110 may be provided in one of the pixel regions PXR. In some embodiments, a reference photodiode region 111 may be provided in the first reference pixel region RPR1. The first substrate 100 may be doped with dopants having a first conductivity type, and the photodiode regions 110 and the reference photodiode region 111 may be doped with dopants having a second conductivity type different from the first conductivity type. For example, the first conductivity type may be a P-type, and the second conductivity type may be an N-type. The second reference pixel region RPR2 may not include the photodiode region.

A floating diffusion region FD may also be provided in the corresponding active region of each of the first and second reference pixel regions RPR1 and RPR2, and a transfer gate TG may be provided on the corresponding active region of each of the first and second reference pixel regions RPR1 and RPR2 with a gate dielectric layer interposed therebetween. The other gates may be provided on the corresponding active region of each of the first and second reference pixel regions RPR1 and RPR2. The floating diffusion region FD, the transfer gate TG, and the other gates of each of the first and second reference pixel regions RPR1 and RPR2 may have substantially the same forms as the floating diffusion region FD, the transfer gate TG, and the other gates of each of the pixel regions PXR.

The deep trench isolation pattern DTI, the shallow trench isolation pattern STI, the photodiode regions 110, the reference photodiode region 111, the floating diffusion regions FD, and the transfer gates TG may be included in the photoelectric conversion layer 10.

The pixels including the photodiode regions 110 of the pixel array region AR may convert incident light into electrical signals (for example, pixel signals). A first reference pixel may include the reference photodiode region 111, the floating diffusion region FD, and the gates of the first reference pixel region RPR1, and a second reference pixel may include the floating diffusion region FD and the gates of the second reference pixel region RPR2. The second reference pixel may not include the photodiode region. Since the first and second reference pixels are disposed in the optical black region OBR, the incident light may not be incident onto the first and second reference pixels. The first reference pixel may generate a first reference charge amount in a dark state to output a first noise signal, and the second reference pixel may generate a second reference charge amount in the dark state to output a second noise signal. Noise components of the pixel signals output from the pixels in the pixel array region AR may be removed using the first and second noise signals.

The light transmission layer 30 may be provided on the second surface 100b of the first substrate 100. The light transmission layer 30 may include a fixed charge layer 310, an antireflective layer 320, a capping insulating layer 330, a grid pattern 340, a protective layer 350, color filters CF1, CF2, and CF3, and microlenses ML.

The fixed charge layer 310 may cover the second surface 100b of the first substrate 100, and the antireflective layer 320 may be disposed on the fixed charge layer 310. In one embodiment, the antireflective layer 320 may include a first sub-antireflective layer 321 and a second sub-antireflective layer 323. The contents related to the first and second sub-antireflective layers 321 and 323 may be the same as those described above in FIGS. 3A to 6.

The first wiring layer 20 may be provided on the first surface 100a of the first substrate 100. The first wiring layer 20 may cover the first surface 100a of the first substrate 100 and include first interlayer insulating layers ILD1 and first wiring lines ICL1. The first wiring lines ICL1 may be provided between the first interlayer insulating layers ILD1. The first wiring lines ICL1 may be electrically connected to pixel transistors (e.g., a transfer transistor, a reset transistor RX, a source follower transistor SF, and a selection transistor SEL) and/or may electrically connect the pixel transistors through first contact plugs.

The second structure S2 may include a second substrate 200, peripheral transistors PTR formed on an upper surface of the second substrate 200, and a second wiring layer 40 provided on the upper surface of the second substrate 200 to cover the peripheral transistors PTR. The second substrate 200 may be a semiconductor substrate such as a silicon substrate, a germanium substrate, or a silicon-germanium substrate. The second wiring layer 40 may include second interlayer insulating layers ILD2 and second wiring lines ICL2 between the second interlayer insulating layers ILD2. The second wiring lines ICL2 may be electrically connected to the peripheral transistors PTR and/or may electrically connect the peripheral transistors PTR through second contact plugs. The second wiring lines ICL2 and the peripheral transistors PTR may configure peripheral circuits (e.g., a row decoder, a row driver, a column decoder, a timing generator, a correlated double sampler, an analog-to-digital converter, and/or an input/output buffer) of the image sensor.

The first structure S1 may be stacked on the second structure S2, and the first and second structures S1 and S2 may be bonded to each other. The second wiring layer 40 may be disposed between the first wiring layer 20 and the second substrate 200. In some embodiments, the lowermost one of the first interlayer insulating layers ILD1 may be bonded to the uppermost one of the second interlayer insulating layers ILD2.

In some embodiments, the first structure S1 may be electrically connected to the second structure S2 through one or more connection structures 50 and 60. In some embodiments, the connection structures 50 and 60 may include a first connection structure 50 and a second connection structure 60.

The first connection structure 50 may include a first through electrode 51, a first filling insulation pattern 52, and a first capping pattern 53. The first through electrode 51 may be provided in a first through hole TH1 that passes through some of the first substrate 100, the first wiring layer 20, and the second wiring layer 40 of the optical black region OBR. In one embodiment, the first through hole TH1 may also pass through the fixed charge layer 310 and the antireflective layer 320. The first through electrode 51 may conformally cover an inner surface of the first through hole TH1. The first through hole TH1 may expose corresponding ones of the first wiring lines ICL1 and corresponding ones of the second wiring lines ICL2. Therefore, the first through electrode 51 may be electrically connected to the corresponding ones of the first wiring lines ICL1 and the corresponding ones of the second wiring lines ICL2. The first filling insulation pattern 52 may be provided on the first through electrode 51 to fill the first through hole TH1. The first capping pattern 53 may cover an upper surface of the first filling insulation pattern 52.

According to some embodiments, a first recess RS1 may be recessed into the first substrate 100 from the second surface 100b of the first substrate 100 of the optical black region OBR. The first recess RS1 may expose a buried conductive pattern of the deep trench isolation pattern DTI. In one embodiment, the first recess RS1 may pass through the fixed charge layer 310 and the antireflective layer 320. The first recess RS1 may be disposed at one side of the first through hole TH1. For example, the first recess RS1 may be disposed between the first through hole TH1 and the second reference pixel region RPR2. The first through electrode 51 may extend onto the second surface 100b of the first substrate 100 and an inner surface of the first recess RS1. Therefore, the first through electrode 51 may be electrically connected to the buried conductive pattern of the deep trench isolation pattern DTI. During operation of an image sensor, a negative bias voltage may be applied to the buried conductive pattern of the deep trench isolation pattern DTI through the first through electrode 51. In one embodiment, the first through electrode 51 may further extend to cover the first and second reference pixel regions RPR1 and RPR2. A portion of the first through electrode 51 covering the first and second reference pixel regions RPR1 and RPR2 may function as a light shielding pattern. In one embodiment, unlike what is shown in FIG. 8, the portion of the first through electrode 51 that functions as the light shielding pattern may be separated from a portion of the first through electrode 51 that covers the inner surfaces of the first recess RS1 and the first through hole TH1.

A conductive plug 70 may fill the remaining region of the first recess RS1. The conductive plug 70 may be in contact with the first through electrode 51 provided in the first recess RS1. In one embodiment, the conductive plug 70 may be formed of a conductive material having a lower resistance than that of the first through electrode 51.

As shown in FIG. 8, the protective layer 350 may cover the first through electrode 51 and the conductive plug 70. For example, the protective layer 350 may contact upper surfaces of the first through electrode 51 and the conductive plug 70. In the first through hole TH1, the protective layer 350 may be provided between the first through electrode 51 and the first filling insulation pattern 52. For example, the protective layer 350 may contact surfaces of the protective layer 350 and surfaces of the first filling insulation pattern 52.

A filtering pattern 80 may cover the first through electrode 51 and the first capping pattern 53. For example, the filtering pattern 80 may extend across the optical black region OBR, contacting upper surfaces of the protective layer 350 and the first capping pattern 53 in the optical black region OBR. The filtering pattern 80 may block light of a specific wavelength range. For example, the filtering pattern 80 may block ultraviolet light. For example, the filtering pattern 80 may include a blue color filter, but is not limited thereto.

The second connection structure 60 may include a second through electrode 61, a second filling insulation pattern 62, and a second capping pattern 63. The second through electrode 61 may be provided in a second through hole TH2 that passes through at least some of the first substrate 100, the first wiring layer 20, and the second wiring layer 40 of the pad region PR. In one embodiment, the second through hole TH2 may further pass through the fixed charge layer 310 and the antireflective layer 320. The second through electrode 61 may conformally cover an inner surface of the second through hole TH2. The second through hole TH2 may expose corresponding ones of the second wiring lines ICL2, and accordingly, the second through electrode 61 may be electrically connected to the corresponding ones of the second wiring lines ICL2. The second filling insulation pattern 62 may be provided on the second through electrode 61 to fill the second through hole TH2. The second capping pattern 63 may cover an upper surface of the second filling insulation pattern 62.

According to some embodiments, a second recess RS2 may be recessed into the first substrate 100 from the second surface 100b of the first substrate 100 of the pad region PR. The second recess RS2 may be disposed at one side of the second through hole TH2. In one embodiment, the second recess RS2 may further pass through the fixed charge layer 310 and the antireflective layer 320. In some embodiments, the second through electrode 61 may extend onto the second surface 100b of the first substrate 100 and an inner surface of the second recess RS2.

A connection pad CP may fill the remaining region of the second recess RS2. The connection pad CP may be in contact with the second through electrode 61. Therefore, the connection pad CP may be electrically connected to the second structure S2 through the second through electrode 61. The connection pad CP may be used for electrical connection with an external device. In some embodiments, the connection pad CP may receive various signals (e.g., command signals and/or control signals) transmitted from the external device, and various electrical signals generated from the image sensor may be transmitted to the external device through the connection pad CP. For example, a connector such as a bonding wire may be connected to the connection pad CP, and the connection pad CP may be electrically connected to the external device through the connector. In one embodiment, the connection pad CP may be formed of a conductive material having a lower resistance than that of the second through electrode 61.

Each of the first and second through electrodes 51 and 61 may be formed of a conductive material. For example, the first and second through electrodes 51 and 61 may be formed of a metal (e.g., tungsten (W), titanium (Ti), tantalum (Ta), etc.) and/or a conductive metal nitride (e.g., titanium nitride (TiN), tantalum nitride (TaN), tungsten nitride (WN), etc.). In one embodiment, the first and second through electrodes 51 and 61 may be formed of the same material. Each of the first and second filling insulation patterns 52 and 62 may be formed of an insulating material. In one embodiment, the first and second filling insulation patterns 52 and 62 may be formed of the same insulating material. Each of the first and second capping patterns 53 and 63 may be formed of an insulating material. In one embodiment, the first and second capping patterns 53 and 63 may be formed of the same insulating material. As described above, the resistance of the conductive plug 70 may be lower than that of the first through electrode 51, and the resistance of the connection pad CP may be lower than that of the second through electrode 61. In one embodiment, the conductive plug 70 and the connection pad CP may be formed of the same conductive material. For example, the conductive plug 70 and the connection pad CP may include aluminum (Al).

A passivation layer 90 may be provided on the second surface 100b of the first substrate 100. The passivation layer 90 may cover the optical black region OBR and the pad region PR. The passivation layer 90 may cover the filtering pattern 80 and the second capping pattern 63. The passivation layer 90 may contact upper surfaces of the filtering pattern 80 and the second capping pattern 63. The passivation layer 90 may include an opening 95 exposing the connection pad CP. In one embodiment, the passivation layer 90 may be formed of a material identical to that of the microlens ML.

In the above-described embodiment, the connection pad CP may be disposed in the second recess RS2 formed in the first substrate 100. However, the embodiments of the present disclosure are not limited thereto. In some embodiments, the connection pad CP may be disposed elsewhere.

In one embodiment, the first sub-antireflective layer 321 may not cover the optical black region OBR and the pad region PR. For example, the antireflective layer 320 covering the optical black region OBR and the pad region PR may be the second sub-antireflective layer 323. Therefore, the first sub-antireflective layer 321 may be electrically isolated from the first and second through electrodes 51 and 61. Therefore, the image sensor according to one embodiment of the present disclosure may reduce the generation of leakage current. As a result, the reliability of the image sensor may be improved.

Furthermore, since the first sub-antireflective layer 321 is provided only on some of the pixel regions PXR, a process for electrically isolating the first and second through electrodes 51 and 61 from the antireflective layer 320 may be omitted. Therefore, the efficiency of the manufacturing process of the image sensor may be improved. As a result, the productivity of the image sensor may be enhanced.

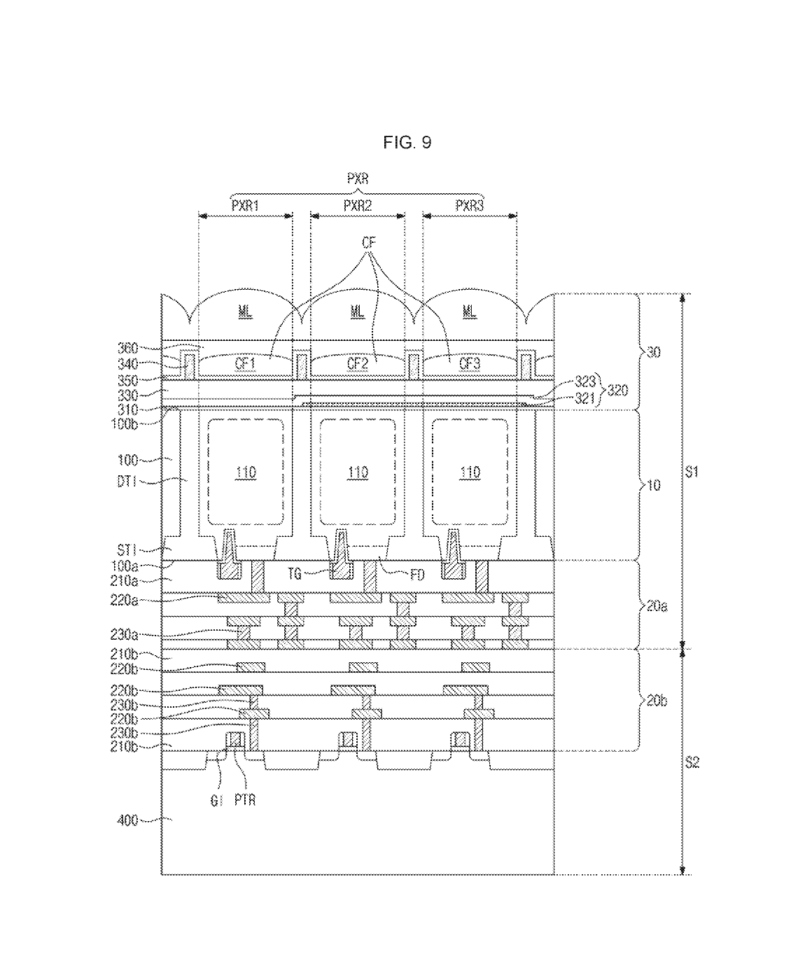

FIG. 9 is a cross-sectional view of an image sensor according to an example embodiment of the present disclosure. For convenience of explanation, the following description will focus on the differences from the above-described embodiments, and duplicative descriptions may not be repeated.

Referring to FIG. 9, the image sensor according to one embodiment of the present disclosure may include a first structure S1 and a second structure S2. The first structure S1 may be disposed on the second structure S2. The first structure S1 may include a light transmission layer 30, a photoelectric conversion layer 10, and a first circuit wiring layer 20a. The photoelectric conversion layer 10 may be disposed between the light transmission layer 30 and the first circuit wiring layer 20a.

The light transmission layer 30 may include the microlenses ML, the color filters CF (e.g., first, second, and third color filters CF1, CF2, and CF3), the planarized pattern 360, the grid pattern 340, the protective layer 350, the capping insulating layer 330, the antireflective layer 320, and the fixed charge layer 310 of FIGS. 3A to 6. The photoelectric conversion layer 10 may include the first substrate 100, the photodiode region 110, the deep trench isolation pattern DTI, the shallow trench isolation pattern STI, the transfer gates TG, the floating diffusion regions FD, and the gates and the source/drain regions of the logic transistors (e.g., reset transistor RX, selection transistor SEL, and source follower transistor SF in FIG. 2) of FIGS. 3A to 6. The first circuit wiring layer 20a may include first interlayer insulating layers 210a, first wirings 220a, and first contact plugs 230a. Here, the first interlayer insulating layers 210amay correspond to the interlayer insulating layers ILD of FIGS. 3A to 6, and the first wirings 220a and the first contact plugs 230a may correspond to the wiring lines ICL of FIGS. 3A to 6.

The second structure S2 may include a second substrate 400 and a second circuit wiring layer 20b on the second substrate 400. Peripheral circuit transistors PTR may be formed on the second substrate 400. The second circuit wiring layer 20b may include second interlayer insulating layers 210b, second wirings 220b, and second contact plugs 230b that cover the peripheral circuit transistors. The second wirings 220b and the second contact plugs 230b may be provided in the second interlayer insulating layers 210b to electrically connected to the peripheral circuit transistors.

The second structure S2 may include various peripheral circuits (e.g., the row decoder 2, the row driver 3, the column decoder 4, the timing generator 5, the CDS 6, the ADC 7, the I/O buffer 8 of FIG. 1, and an autofocus circuit) to operate the pixels in the first structures S1. For example, the second wirings 220b, the second contact plugs 230b, and the peripheral circuit transistors may configure various peripheral circuits.

The second circuit wiring layer 20b may be disposed between the first circuit wiring layer 20a and the second substrate 400. The lowermost one of the first interlayer insulating layers 210a may be bonded to the uppermost one of the second interlayer insulating layers 210b. The first structure S1 may be electrically connected to the second structure S2 through through-electrodes (not shown) in an edge region of the first structure S1. Alternatively, a first bonding pad (not shown) may be disposed in the lowermost first interlayer insulating layer 210a, a second bonding pad (not shown) may be disposed in the uppermost second interlayer insulating layer 210b, and the first bonding pad may be bonded to the second bonding pad. In this case, the first structure S1 may be electrically connected to the second structure S2 through the first and second bonding pads. The first and second bonding pads may be formed of or include copper (Cu).

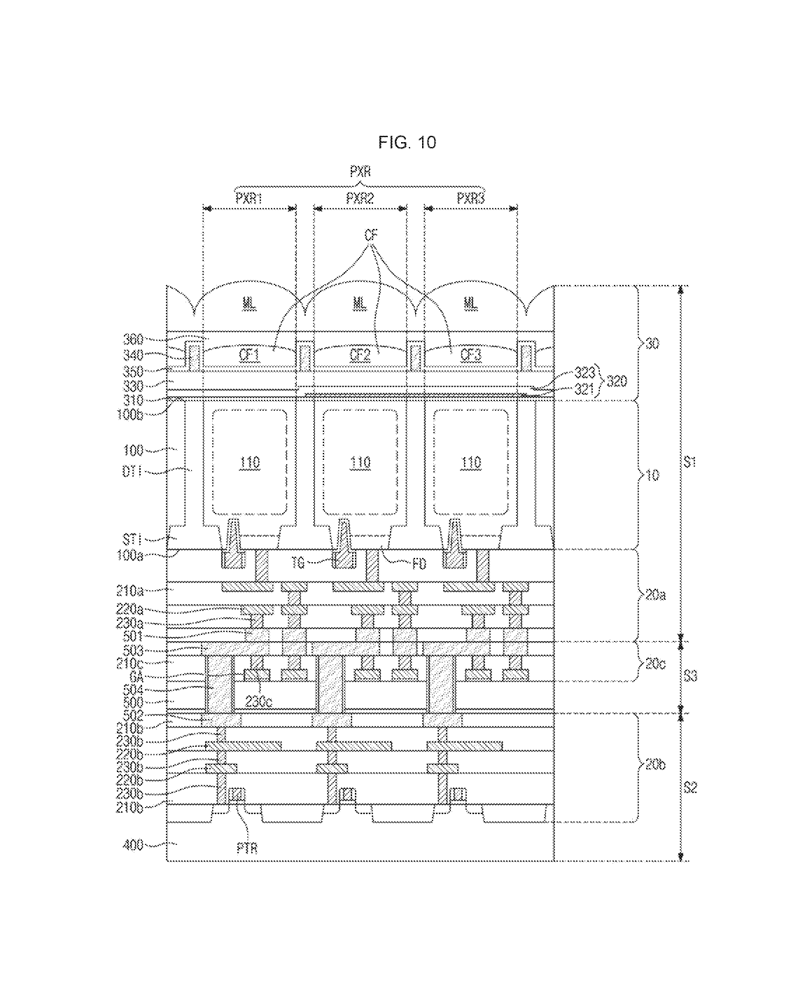

FIG. 10 is a cross-sectional view of an image sensor according to an example embodiment of the present disclosure. For convenience of explanation, the following description will focus on the differences from the above-described embodiments, and duplicative descriptions may not be repeated.

Referring to FIG. 10, the image sensor according to one embodiment of the present disclosure may include a first structure S1, a second structure S2, and a third structure S3. The third structure S3 may be disposed between the first structure S1 and the second structure S2.

The first structure S1 may include a light transmission layer 30, a photoelectric conversion layer 10, and a first circuit wiring layer 20a. The light transmission layer 30 may be the same as the light transmission layer 30 of FIG. 9. The photoelectric conversion layer 10 may include the first substrate 100, the photodiode region 110, the deep trench isolation pattern DTI, the shallow trench isolation pattern STI, the transfer gates TG, the floating diffusion regions FD, and the gates and the source/drain regions of the logic transistors (e.g., reset transistor RX, selection transistor SEL, and source follower transistor SF of FIG. 2) of FIGS. 3A to 6. The first circuit wiring layer 20a may include first interlayer insulating layers 210a, first wirings 220a, first contact plugs 230a, and first bonding pads 501. Here, the first interlayer insulating layers 210amay correspond to the interlayer insulating layers ILD of FIGS. 3A to 6, and the first wirings 220a and the first contact plugs 230a may correspond to the wiring lines ICL of FIGS. 3A to 6. The first bonding pads 501 may be disposed in the lowermost one of the first interlayer insulating layers 210a, and may have lower surfaces that are coplanar with a lower surface of the lowermost one of the first interlayer insulating layers 210a.

The second structure S2 may include a second substrate 400 and a second circuit wiring layer 20b on the second substrate 400. The second structure S2 may be substantially the same as the second structure S2 of FIG. 9. However, the second structure S2 may further include second bonding pads 502 provided in the uppermost one of the second interlayer insulating layers 210b. For example, upper surfaces of the second bonding pads 502 may be coplanar with an upper surface of the uppermost one of the second interlayer insulating layers 210b.

The third structure S3 may include a third substrate 500, gates GA on the third substrate 500, and a third circuit wiring layer 20c provided on the third substrate 500. The third substrate 500 may be a semiconductor substrate. Each of the gates GA may be disposed on the third substrate 500 with a gate dielectric layer interposed therebetween. Source/drain regions (not shown) may be provided in the third substrate 500 at both sides of each of the gates GA.

The third circuit wiring layer 20c may include third interlayer insulating layers 210c, third contact plugs 230c, third bonding pads 503, and fourth bonding pads 504. Although not shown, the third circuit wiring layer 20c may further include third wirings, and each of the third wirings may be electrically connected to a corresponding gate GA, a corresponding source/drain region, a corresponding third bonding pad 503, and/or a corresponding fourth bonding pad 504.

According to one embodiment, the first structure S1 may include some components of the pixel PXL of FIG. 2 and the third structure S3 may include other components of the pixel PXL of FIG. 2. For example, the first structure S1 may include the photodiode PD, the transfer transistor, and the floating diffusion region FD, and the third structure S3 may include the logic transistors RX, SEL, and SF of the pixel PXL.

In one embodiment, the logic transistors RX, SEL, and SF may be provided on the third substrate 500 under each of the pixel regions PXR. In this case, the pixel formed in each of the pixel regions PXR may include all the pixel transistors. Alternatively, the transistors on the third substrate 500 may be disposed so that a pair of sub-pixels formed in each of the pixel regions PXR shares at least one of the logic transistors RX, SEL, and SF.

According to one embodiment, the first structure S1 and the third structure S3 may be bonded to each other by a copper-to-copper bonding method, and the third structure S3 and the second structure S2 may also be bonded to each other by the copper-to-copper bonding method. For example, the bonding pads 501, 502, 503, and 504 of the first, second, and third structures S1, S2, and S3 may be formed of copper. The first bonding pad 501 of the first structure S1 may be bonded to the third bonding pad 503 of the third structure S3, and the second bonding pad 502 of the second structure S2 may be bonded to the fourth bonding pad 504 of the third structure S3. In one embodiment, the fourth bonding pad 504 may be bonded to the second bonding pad 502 by passing through the third substrate 500.

Meanwhile, methods for manufacturing the image sensors according to some embodiments of the present disclosure will be described below.

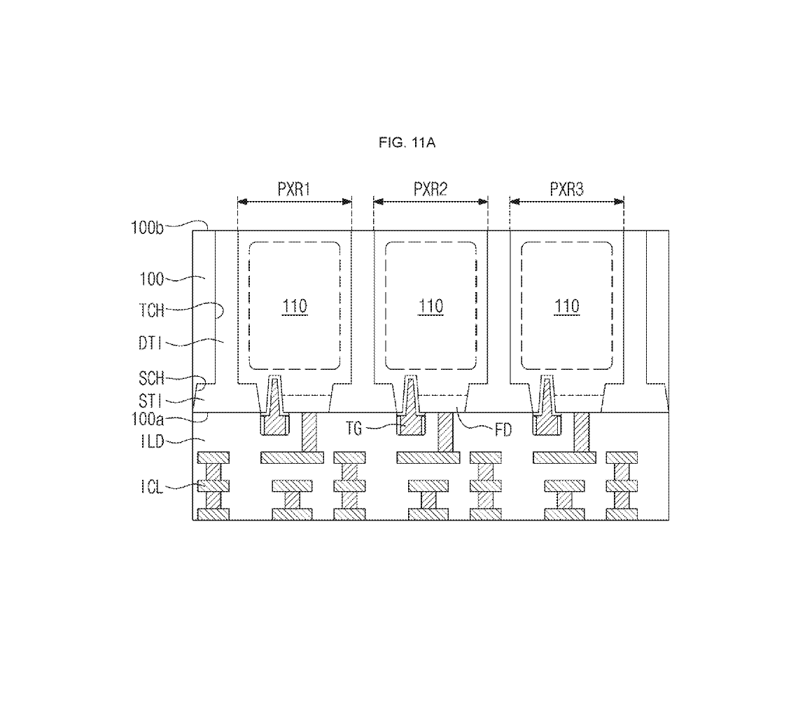

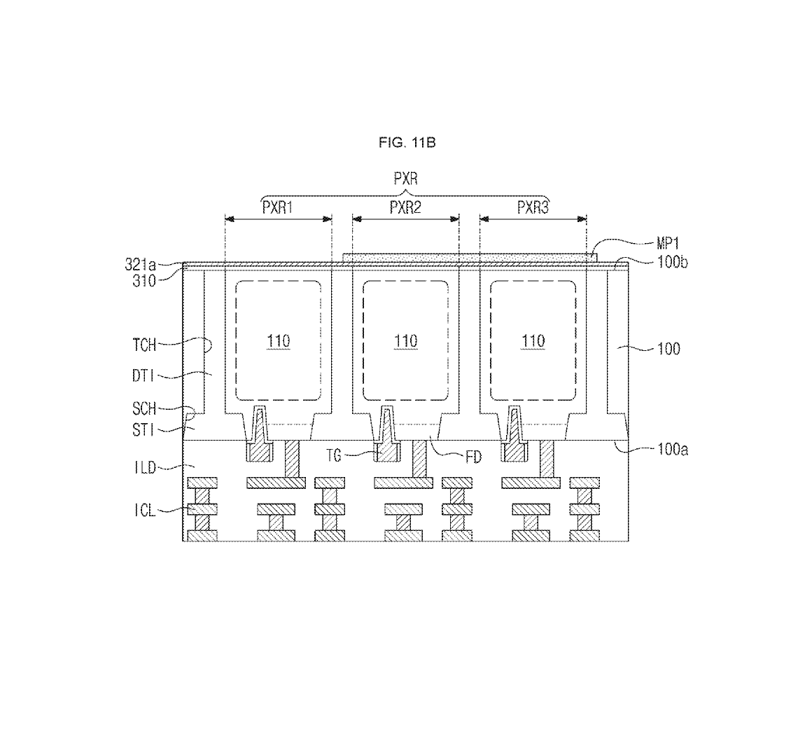

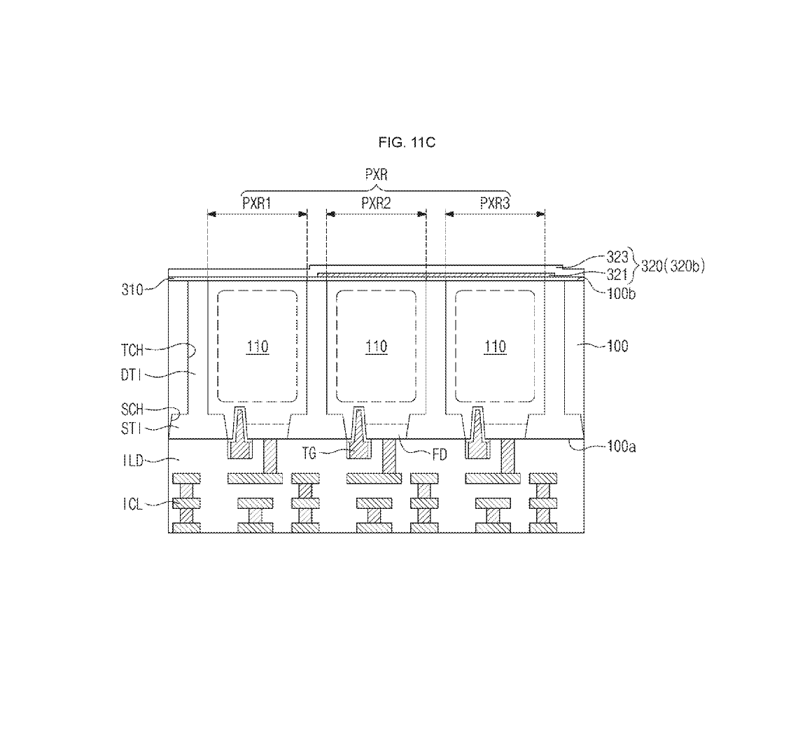

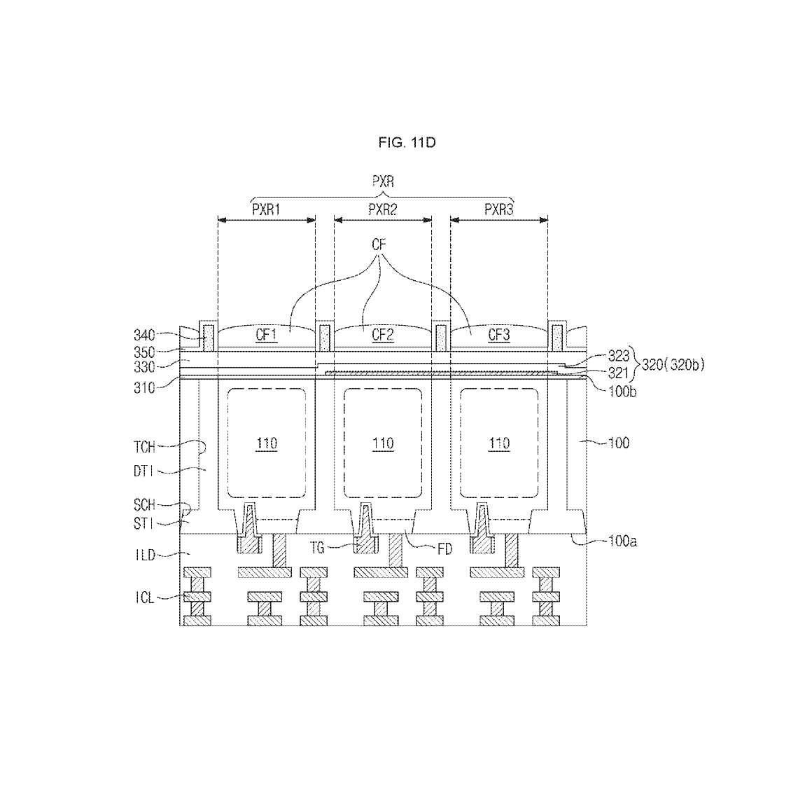

FIGS. 11A to 11D are cross-sectional views illustrating a method for manufacturing an image sensor according to an example embodiment of the present disclosure.

Referring to FIG. 11A, a patterning process may be performed so that a shallow trench SCH may be recessed from a first surface 100a of a substrate 100. Thereafter, a shallow trench isolation pattern STI may be formed on the first surface 100a of the substrate 100 through a deposition process or an oxidation process to fill the shallow trench SCH. The shallow trench isolation pattern STI may be provided in the shallow trench SCH to define active regions. Each of the active regions may be a portion of the substrate 100 surrounded by the shallow trench isolation pattern STI in a plan view.

Next, the substrate 100 may be patterned to form a deep trench TCH. The deep trench TCH may extend from the first surface 100a toward a second surface 100b of the substrate 100, but is not limited thereto. In one embodiment, the deep trench TCH may extend from the second surface 100b toward the first surface 100a of the substrate 100 and may be connected to the shallow trench SCH. The deep trench TCH may define pixel regions PXR, for example, first, second, and third pixel regions PXR1, PXR2, and PXR3. In addition, a deep trench isolation pattern DTI may be formed through a deposition process or an oxidation process to fill the deep trench TCH.

Impurities of a second conductivity type may be implanted into the substrate 100 so that a photodiode region 110 may be formed in each of the pixel regions PXR. In one embodiment, the photodiode regions 110 may be formed before the formation of the shallow trench SCH or before the formation of the deep trench isolation pattern DTI.

A gate trench may be formed in the corresponding active region of each of the pixel regions PXR. A gate dielectric layer may be formed on inner surfaces of the gate trenches and on the active regions, and a gate conductive layer may be formed on the gate dielectric layer. The gate conductive layer may fill the gate trenches. The gate conductive layer may be patterned to form transfer gates TG. In this case, gates of logic transistors may also be formed on the corresponding active regions of each of the pixel regions PXR.

Impurities of the second conductivity type may be implanted into the active regions defined by the shallow trench isolation pattern STI to form floating diffusion regions FD. The floating diffusion regions FD may be formed between the photodiode region 110 and the first surface 100a of the substrate 100. The floating diffusion regions FD may be provided between the transfer gates TG.

An interlayer insulating layer ILD may be formed on the first surface 100a of the substrate 100. Wiring lines ICL may be formed on the first surface 100a of the substrate 100. The wiring lines ICL may be formed between the interlayer insulating layer ILD. The wiring lines ICL may include wirings and contact plugs. The wiring lines ICL may be connected to the floating diffusion regions FD. In order to implement the pixel PXL of FIG. 2, the wiring lines ICL may pass through the interlayer insulating layer ILD and may be connected to the floating diffusion regions FD. Subsequent processes may be performed on the first surface 100a of the substrate 100. After the subsequent processes on the first surface 100a are completed, the substrate 100 may be flipped to be oriented as illustrated in FIG. 11A.

In one embodiment, the wiring lines ICL including the contact plugs and the wirings, and the interlayer insulating layer ILD may be substantially the same as the first contact plug 230a, the first wirings 220a, and the first interlayer insulating layer 210a that are shown in FIGS. 9 and 10, respectively.

In one embodiment, the formation of the deep trench TCH and the deep trench isolation pattern DTI may be performed after the substrate 100 is flipped. For example, the deep trench TCH and the deep trench isolation pattern DTI may be formed after the subsequent processes on the first surface 100a are completed.

After the substrate 100 is flipped, a planarization process may be performed until the second surface 100b of the substrate 100 is exposed. The planarization process may be performed using at least one of an etch-back process or a chemical mechanical polishing process. A hydrogen/deuterium annealing process may be performed to heal defects (e.g., dangling bonds, etc.) of the polished second surface 100b of the substrate 100.

In one embodiment, as shown in FIG. 9, the second structure S2 (see FIG. 9) may be bonded to the substrate 100. The bonding may be performed through a copper-to-copper bonding process and/or a silicon oxide-to-silicon oxide bonding process. However, the bonding method is not limited thereto, and various bonding processes may be performed.

In one embodiment, as shown in FIG. 10, the third structure S3 (see FIG. 10) may be bonded to the substrate 100. In this case, the third structure S3 (see FIG. 10) may be already in a state of being bonded to the second structure S2 (see FIG. 10). The bonding may be performed through a copper-to-copper bonding process and/or a silicon oxide-to-silicon oxide bonding process. However, the bonding method is not limited thereto, and various bonding processes may be performed.

Referring to FIG. 11B, a fixed charge layer 310 may be formed on the second surface 100b of the substrate and on an upper surface of the deep trench isolation pattern DTI. The fixed charge layer 310 may contact the second surface 100b of the substrate and the upper surface of the deep trench isolation pattern DTI. The fixed charge layer 310 may be conformally formed and its thickness may vary depending on the pixel regions PXR. The fixed charge layer 310 may be formed by, for example, a deposition process and/or an oxidation process.

Thereafter, a first preliminary antireflective layer 321a may be formed on an upper surface of the fixed charge layer 310. The first preliminary antireflective layer 321a may be conformally formed. The first preliminary antireflective layer 321a may be formed by, for example, a deposition process and/or an oxidation process.

Next, a first mask pattern MP1 may be formed on the first preliminary antireflective layer 321a. Specifically, the first mask pattern MP1 may be provided on portions of the first preliminary antireflective layer 321a corresponding to the second and third pixel regions PXR2 and PXR3. In this case, the first mask pattern MP1 may be formed of a material having etch selectivity with respect to the first preliminary antireflective layer 321a. The first mask pattern MP1 may be, for example, a photoresist or a hard mask.

Referring to FIG. 11C, a patterning process may be performed so that the first preliminary antireflective layer 321a may be patterned. The first preliminary antireflective layer 321a may be etched using the first mask pattern MP1 as an etch mask. For example, the first preliminary antireflective layer 321a may be etched through a wet etching process. Therefore, a first sub-antireflective layer 321 may be formed. The first sub-antireflective layer 321 may be formed, for example, on the second and third pixel regions PXR2 and PXR3. After the first sub-antireflective layer 321 is formed, the first mask pattern MP1 may be removed through a separate etching process or cleaning process.

Thereafter, a second sub-antireflective layer 323 may be conformally formed on the fixed charge layer 310 and the first sub-antireflective layer 321. The second sub-antireflective layer 323 may cover the first sub-antireflective layer 321. The second sub-antireflective layer 323 may be formed through a deposition process. For example, the second sub-antireflective layer 323 may be formed by a chemical vapor deposition (CVD) method, a physical vapor deposition (PVD) method, or an atomic layer deposition (ALD) method. For example, the second sub-antireflective layer 323 may be formed by a co-deposition method or a cyclic deposition method. The first and second sub-antireflective layers 321 and 323 may constitute the antireflective layer 320 of FIGS. 3A-3B or the antireflective layer 320b of FIG. 5.

Referring to FIG. 11D, a capping insulating layer 330 may be formed on the antireflective layers 320 or 320b. The capping insulating layer 330 may be formed through a deposition process and/or an oxidation process.

Thereafter, a patterning process may be performed to form a grid pattern 340. The grid pattern 340 may be formed corresponding to boundaries of the pixel regions PXR. The grid pattern 340 may be formed, for example, over the deep trench isolation pattern DTI. After the grid pattern 340 is formed, a deposition process or an oxidation process may be performed to form a protective layer 350. The protective layer 350 may be formed on the grid pattern 340 and the capping insulating layer 330.

Thereafter, color filters CF may be disposed on the capping insulating layer 330. The color filters CF may be arranged two-dimensionally. The color filters CF may include a first color filter CF1, a second color filter CF2, and a third color filter CF3 that have different colors. Each of the color filters CF may be disposed on the corresponding one of the pixel regions PXR. For example, the first color filter CF1 may be disposed on the first pixel region PXR1. For example, the second color filter CF2 may be disposed on the second pixel region PXR2. For example, the third color filter CF3 may be disposed on the third pixel region PXR3.

Referring back to FIG. 3A, the planarization pattern 360 may be formed on the color filters CF. The planarization pattern 360 may be formed by being applied using an organic polymer and then cured. In one embodiment, the planarization pattern 360 may be a material in a liquid form. The planarization pattern 360 may be applied flatly on the color filters CF. For example, the planarization pattern 360 may reduce height differences between surfaces of the color filters CF and may provide a uniform surface on which subsequent processes are performed. Thereafter, a heat treatment process may be performed to cross-link the planarization pattern 360, thereby curing the planarization pattern 360.

Thereafter, microlenses ML may be formed on the planarization pattern 360, thereby manufacturing the image sensor as shown in FIG. 3A.

In one embodiment, when a process such as that shown in FIG. 11D is performed, the placement of the color filter CF on the third pixel region PXR3 may be omitted. For example, the third color filter CF3 may not be disposed on the third pixel region PXR3. Thereafter, when the planarization pattern 360 is formed, the planarization pattern 360 may fill a space in which the third color filter CF3 is not disposed. Thereafter, the microlenses ML may be formed on the planarization pattern 360, thereby manufacturing the image sensor as shown in FIG. 5.

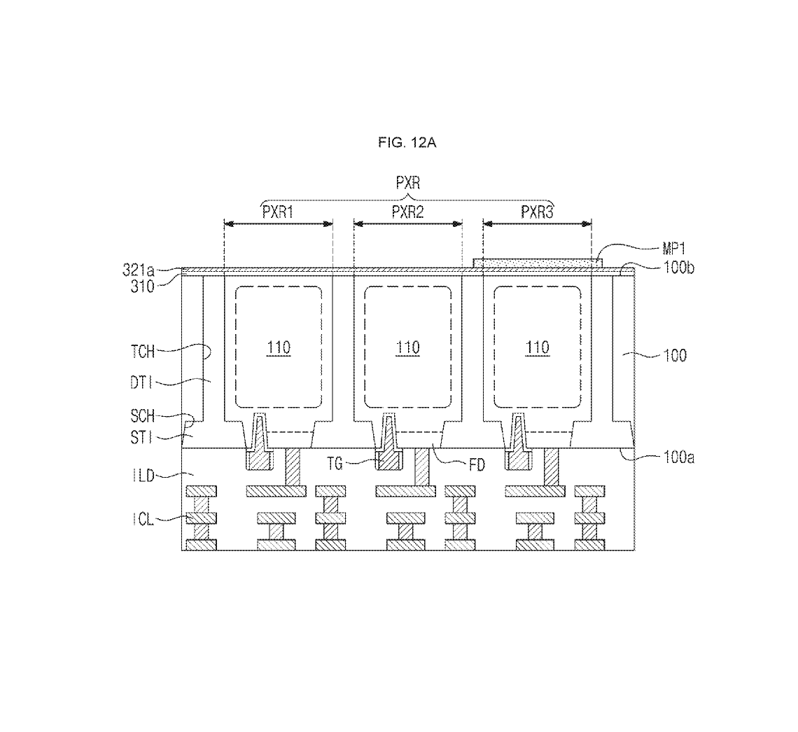

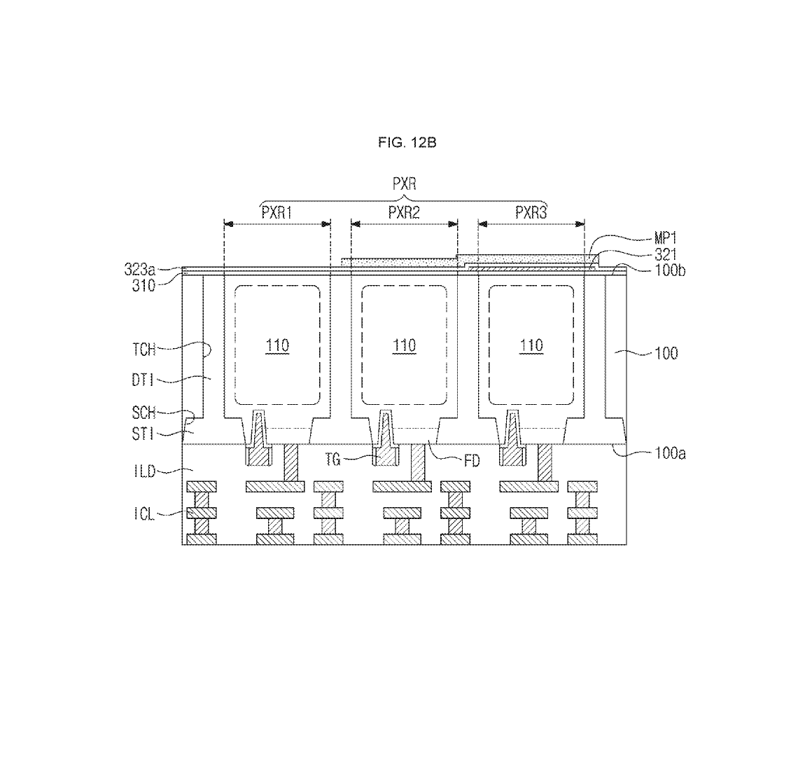

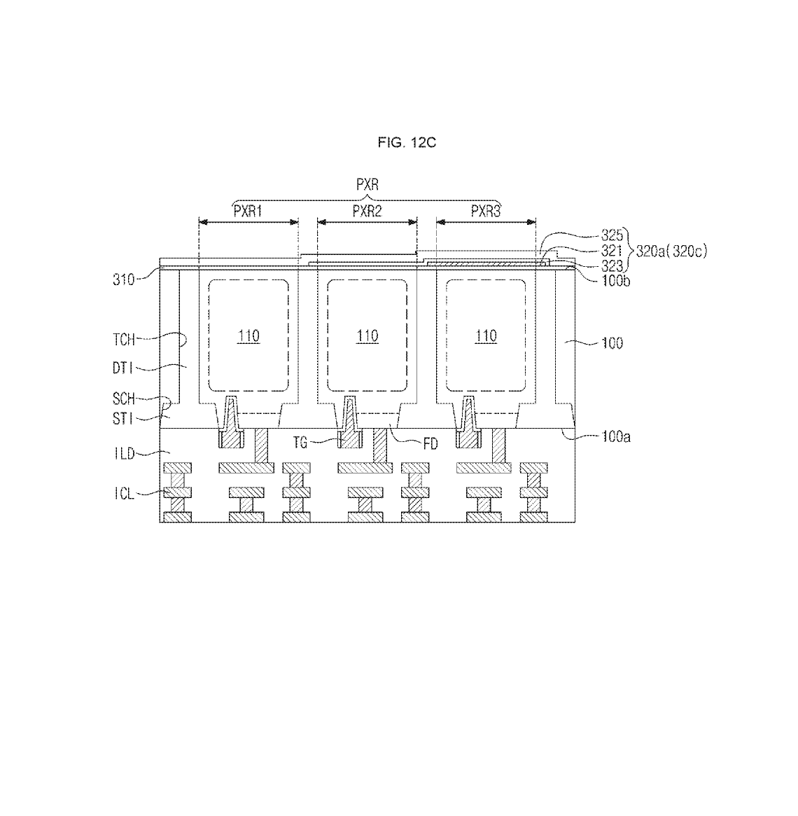

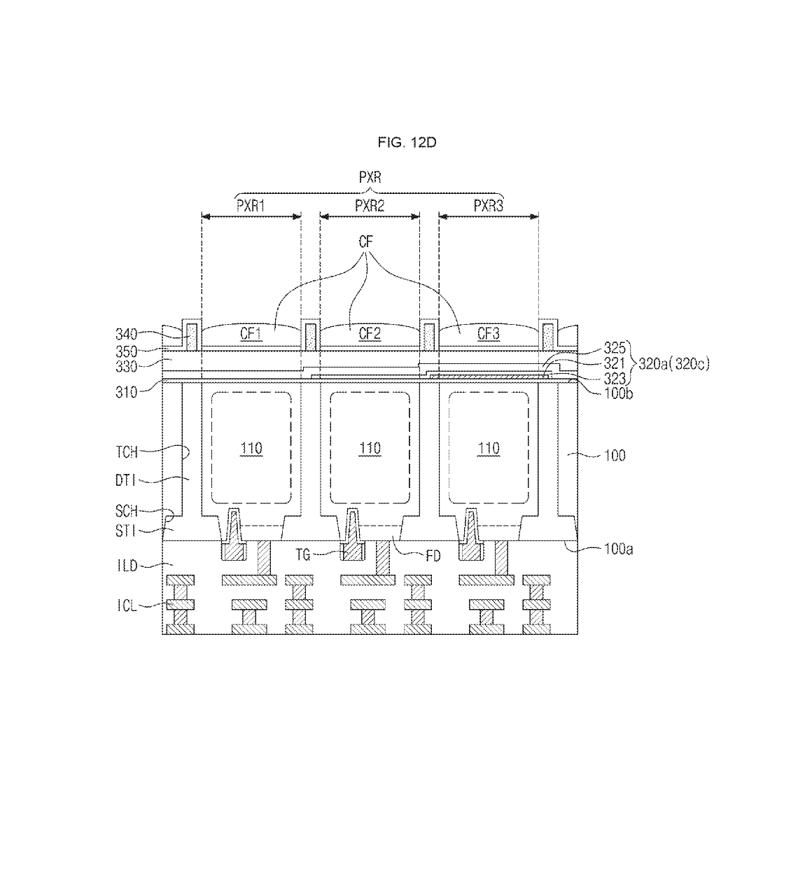

FIGS. 12A to 12D are cross-sectional views illustrating a method for manufacturing an image sensor according to an example embodiment of the present disclosure. For convenience of explanation, the differences from the above-described manufacturing method will be mainly described.

Referring to FIG. 12A, after the process according to FIG. 11A is performed, a fixed charge layer 310 and a first preliminary antireflective layer 321a may be sequentially formed on a second surface 100b of a substrate 100.

Next, a first mask pattern MP1 may be formed on the first preliminary antireflective layer 321a. Specifically, the first mask pattern MP1 may be provided on a portion of the first preliminary antireflective layer 321a corresponding to a third pixel region PXR3. In this case, the first mask pattern MP1 may be formed of a material having etch selectivity with respect to the first preliminary antireflective layer 321a. The first mask pattern MP1 may be, for example, a photoresist or a hard mask.

Referring to FIG. 12B, a patterning process may be performed so that the first preliminary antireflective layer 321a may be patterned. The first preliminary antireflective layer 321a may be etched using the first mask pattern MP1 as an etch mask. Therefore, a first sub-antireflective layer 321 may be formed. The first sub-antireflective layer 321 may be formed, for example, on the third pixel region PXR3. After the first sub-antireflective layer 321 is formed, the first mask pattern MP1 may be removed through a separate etching process or cleaning process.

Thereafter, a second preliminary antireflective layer 323a may be conformally formed on the fixed charge layer 310 and the first sub-antireflective layer 321. The second preliminary antireflective layer 323a may cover the first sub-antireflective layer 321. The second preliminary antireflective layer 323a may be formed through a deposition process. For example, the second preliminary antireflective layer 323a may be formed by a chemical vapor deposition (CVD) method, a physical vapor deposition (PVD) method, or an atomic layer deposition (ALD) method. For example, the second preliminary antireflective layer 323a may be formed by a co-deposition method or a cyclic deposition method.

Next, a second mask pattern MP2 may be formed on the second preliminary antireflective layer 323a. Specifically, the second mask pattern MP2 may be provided on portions of the second preliminary antireflective layer 323a corresponding to the second and third pixel regions PXR2 and PXR3. In this case, the second mask pattern MP2 may be formed of a material having etch selectivity with respect to the second preliminary antireflective layer 323a. The second mask pattern MP2 may be, for example, a photoresist or a hard mask.

Referring to FIG. 12C, a patterning process may be performed so that the second preliminary antireflective layer 323a may be patterned. The second preliminary antireflective layer 323a may be etched using the second mask pattern MP2 as an etch mask. Therefore, a second sub-antireflective layer 323 may be formed. The second sub-antireflective layer 323 may be formed, for example, on the second and third pixel regions PXR2 and PXR3. After the second sub-antireflective layer 323 is formed, the second mask pattern MP2 may be removed through a separate etching process or cleaning process.

Thereafter, a third sub-antireflective layer 325 may be conformally formed on the first and second sub-antireflective layers 321 and 323. The third sub-antireflective layer 325 may cover the second sub-antireflective layer 323. The third sub-antireflective layer 325 may be formed through a deposition process. For example, the third sub-antireflective layer 325 may be formed by a chemical vapor deposition (CVD) method, a physical vapor deposition (PVD) method, or an atomic layer deposition (ALD) method. For example, the third sub-antireflective layer 325 may be formed by a co-deposition method or a cyclic deposition method. The first, second, and third sub-antireflective layers 321, 323, and 325 may constitute the antireflective layer 320a of FIG. 4 or the antireflective layer 320c of FIG. 6.

Referring to FIG. 12D, a deposition process and/or an oxidation process may be performed to form a capping insulating layer 330 on the antireflective layers 320a or 320c. Thereafter, a patterning process may be performed to form a grid pattern 340. After the grid pattern 340 is formed, a deposition process or an oxidation process may be performed to form a protective layer 350. The protective layer 350 may be formed on the grid pattern 340 and the capping insulating layer 330. Thereafter, each of color filters CF may be disposed on one of the pixel regions PXR.

Thereafter, a planarization pattern 360 and microlenses ML may be sequentially formed on the color filters CF, thereby manufacturing the image sensor as shown in FIG. 4.

In one embodiment, when a process such as that shown in FIG. 12D is performed, the placement of the color filter CF on the third pixel region PXR3 may be omitted. For example, the third color filter CF3 may not be disposed on the third pixel region PXR3. Thereafter, when the planarization pattern 360 is formed, the planarization pattern 360 may fill a space in which the third color filter CF3 is not disposed. Thereafter, the microlenses ML may be formed on the planarization pattern 360, thereby manufacturing the image sensor as shown in FIG. 6.

An image sensor according to example embodiments of the present disclosure may improve photoelectric conversion efficiency by minimizing light reflection.

An image sensor according to example embodiments of the present disclosure may improve reliability by reducing the generation of leakage current.

An image sensor according to example embodiments of the present disclosure may enhance productivity by improving process efficiency.

The above-described contents are specific example embodiments for implementing the present disclosure. In addition to the above-described embodiments, the present disclosure will also include embodiments that can be simply designed around or easily changed. In addition, the present disclosure will also include technologies that can be easily modified and implemented using the embodiments. Therefore, the scope of the present disclosure should not be limited to the above-described embodiments, but should be defined not only by the patent claims described below but also by the equivalents of the patent claims of the present disclosure.

What is claimed is:

1. An image sensor, comprising:
a substrate having a first surface and a second surface opposite to the first surface;
color filters on the second surface of the substrate; and
an antireflective layer between the second surface of the substrate and the color filters,
wherein a thickness of the antireflective layer between the second surface and a first color filter of the color filters is smaller than a thickness of the antireflective layer between the second surface and a second color filter of the color filters,
wherein the antireflective layer between the second surface and the second color filter includes a first sub-antireflective layer and a second sub-antireflective layer that are sequentially stacked,
wherein the antireflective layer between the second surface and the first color filter includes the second sub-antireflective layer,
wherein the first sub-antireflective layer includes a metal oxide, and
wherein the second sub-antireflective layer includes an oxygen element, a metal identical to that of the first sub-antireflective layer, and an impurity.

2. The image sensor of claim 1,
wherein the metal oxide includes titanium oxide (TiOₓ), hafnium oxide (HfOₓ), or tantalum oxide (TaOₓ),
wherein the identical metal is titanium (Ti), hafnium (Hf), or tantalum (Ta), and
wherein the impurity is silicon (Si), hafnium (Hf), zirconium (Zr), tantalum (Ta), or aluminum (Al), and includes a material different from the identical metal.

3. The image sensor of claim 1, wherein a band gap energy of the second sub-antireflective layer is greater than a band gap energy of the first sub-antireflective layer.

4. The image sensor of claim 1, wherein an optical refractive index of the first sub-antireflective layer is greater than an optical refractive index of the second sub-antireflective layer.

5. The image sensor of claim 1, wherein a thickness of the second sub-antireflective layer is greater than a thickness of the first sub-antireflective layer.

6. The image sensor of claim 1, further comprising:
a deep trench isolation pattern provided in the substrate to define pixel regions,
wherein the first color filter covers a first one of the pixel regions,
wherein the second color filter covers a second one of the pixel regions, and
wherein the second color filter is configured to transmit light having a wavelength greater than a wavelength of light transmitted by the first color filter.

7. The image sensor of claim 6,
wherein the color filters further include a third color filter covering a third one of the pixel regions,
wherein a thickness of the antireflective layer on the third one of the pixel regions is greater than the thickness of the antireflective layer between the first color filter and the second surface,
wherein the thickness of the antireflective layer on the third one of the pixel regions is substantially the same as the thickness of the antireflective layer between the second color filter and the second surface, and
wherein the antireflective layer on the third one of the pixel regions includes the first sub-antireflective layer and the second sub-antireflective layer that are sequentially stacked.

8. The image sensor of claim 7, wherein the third color filter is configured to transmit light having a wavelength greater than a wavelength of light transmitted by the second color filter.

9. The image sensor of claim 6,
wherein a third one of the pixel regions is not covered by the color filters,
wherein a thickness of the antireflective layer on the third one of the pixel regions is greater than the thickness of the antireflective layer between the first color filter and the second surface, and
wherein the antireflective layer on the third one of the pixel regions includes the first sub-antireflective layer and the second sub-antireflective layer that are sequentially stacked.

10. The image sensor of claim 1, further comprising:
a fixed charge layer between the second surface of the substrate and the antireflective layer,
wherein the fixed charge layer includes negative fixed charges.

11. The image sensor of claim 1, further comprising:
a capping insulating layer provided on an upper surface of the antireflective layer.

12. The image sensor of claim 1, wherein the second sub-antireflective layer is formed by co-deposition or cyclic deposition.

13. An image sensor, comprising:
a substrate having a first surface and a second surface opposite to the first surface;
a deep trench isolation pattern provided in the substrate to define pixel regions, the pixel regions including a first pixel region, a second pixel region, and a third pixel region;
an antireflective layer provided on the second surface of the substrate to cover the pixel regions and including a first sub-antireflective layer, a second sub-antireflective layer, and a third sub-antireflective layer;
a first color filter provided on the antireflective layer and covering the first pixel region; and
a second color filter provided on the antireflective layer and covering the second pixel region,
wherein a thickness of the antireflective layer on the third pixel region is greater than a thickness of the antireflective layer on the second pixel region,
wherein the thickness of the antireflective layer on the second pixel region is greater than a thickness of the antireflective layer on the first pixel region,
wherein the antireflective layer on the third pixel region includes the first, second, and third sub-antireflective layers that are sequentially stacked,
wherein the antireflective layer on the second pixel region includes the second and third sub-antireflective layers that are sequentially stacked,
wherein the antireflective layer on the first pixel region includes the third sub-antireflective layer, and
wherein an optical refractive index of the first sub-antireflective layer is greater than an optical refractive index of the second sub-antireflective layer.

14. The image sensor of claim 13,
wherein the first sub-antireflective layer includes titanium oxide (TiOₓ), hafnium oxide (HfOₓ), or tantalum oxide (TaOₓ), and
wherein the second sub-antireflective layer includes at least one of titanium oxide (TiOₓ), hafnium oxide (HfOₓ), or tantalum oxide (TaOₓ), and at least one of silicon (Si), hafnium (Hf), zirconium (Zr), tantalum (Ta), or aluminum (Al).

15. The image sensor of claim 14,
wherein the third sub-antireflective layer is formed of a material identical to that of the second sub-antireflective layer.

16. The image sensor of claim 13, further comprising:
a third color filter provided on the antireflective layer and covering the third pixel region,
wherein the first color filter is configured to transmit light having a first wavelength, the second color filter is configured to transmit light having a second wavelength, and the third color filter is configured to transmit light having a third wavelength, and wherein the third wavelength is greater than the second wavelength, and the second wavelength is greater than the first wavelength.

17. The image sensor of claim 13,
wherein the third pixel region is not covered by any color filter, and
wherein the third pixel region is configured to detect infrared rays.

18. An image sensor, comprising:
a substrate having a first surface and a second surface opposite to the first surface, the substrate including a pixel array region, a pad region provided at one side of the pixel array region, and an optical black region provided between the pixel array region and the pad region;
an antireflective layer on the second surface of the substrate; and
color filters provided on the antireflective layer and including a first color filter and a second color filter that have different colors from each other,
wherein the color filters are provided on the pixel array region,
wherein a thickness of the antireflective layer between the second color filter and the second surface is greater than a thickness of the antireflective layer between the first color filter and the second surface, and greater than a thickness of the antireflective layer on the optical black region and the pad region,
wherein the antireflective layer between the second color filter and the second surface includes a first sub-antireflective layer and a second sub-antireflective layer that are sequentially stacked, and
wherein the antireflective layer between the first color filter and the second surface includes the second sub-antireflective layer.

19. The image sensor of claim 18,
wherein the antireflective layer on the optical black region and the pad region includes the second sub-antireflective layer.

20. The image sensor of claim 18,
wherein the first sub-antireflective layer includes titanium oxide (TiOₓ), hafnium oxide (HfOₓ), or tantalum oxide (TaOₓ), and
wherein the second sub-antireflective layer includes at least one of titanium oxide (TiOₓ), hafnium oxide (HfOₓ), or tantalum oxide (TaOₓ), and at least one of silicon (Si), hafnium (Hf), zirconium (Zr), tantalum (Ta), or aluminum (Al).
